(19) United States
(12) Patent Application Publication
(10) Pub. No.: US 2024/0395744 A1
(43) Pub. Date: Nov. 28, 2024

(54) PACKAGE STRUCTURE AND METHOD FOR FABRICATING THE SAME

(71) Applicants: TAIWAN SEMICONDUCTOR MANUFACTURING COMPANY, LTD., Hsinchu (TW); NATIONAL YANG MING CHIAO TUNG UNIVERSITY, Hsinchu City (TW)

(72) Inventors: Chih CHEN, Hsinchu City (TW); Yi-Quan LIN, New Taipei City (TW)

(73) Assignees: TAIWAN SEMICONDUCTOR MANUFACTURING COMPANY, LTD., Hsinchu (TW); NATIONAL YANG MING CHIAO TUNG UNIVERSITY, Hsinchu City (TW)

(21) Appl. No.: 18/323,403

(22) Filed: May 24, 2023

(51) Int. Cl. H01L 23/00

(52) U.S. Cl. CPC H01L 24/05; H01L 24/03; H01L 24/13; H01L 24/16; H01L 24/81; H01L 2224/03464; H01L 2224/05083; H01L 2224/05147; H01L 2224/05166; H01L 2224/05611; H01L 2224/05639; H01L 2224/05644; H01L 2224/05664; H01L 2224/13111; H01L 2224/13124; H01L 2224/13139; H01L 2224/13144; H01L 2224/13147; H01L 2224/13155; H01L 2224/13164; H01L 2224/16145; H01L 2224/81801

(57) ABSTRACT

A method includes forming a first conductive feature and a second conductive feature over a first substrate, wherein the first and second conductive features comprise nano-twinned copper; and depositing a first metal cap layer over the first conductive feature and a second metal cap layer over the second conductive feature, wherein the first metal cap layer is spaced apart from the second metal cap layer in a cross-sectional view.

### BACKGROUND

The semiconductor integrated circuit (IC) industry has experienced rapid growth. Technological advances in IC materials and design have produced generations of ICs. Each generation has smaller and more complex circuits than the previous generation. However, these advances have increased the complexity of processing and manufacturing ICs. In the course of IC evolution, functional density (e.g., the number of interconnected devices per chip area) has generally increased while geometric size (e.g., the smallest component (or line) that can be created using a fabrication process) has decreased. This scaling-down process generally provides benefits by increasing production efficiency and lowering associated costs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-5 illustrate a method for fabricating a package structure at various intermediate stages according to some embodiments of the present disclosure.

FIG. 6 is a schematic view of an electroplating apparatus, in accordance with some embodiments.

FIG. 7 is a cross-sectional view of a package structure according to some embodiments of the present disclosure.

FIGS. 8 and 9 illustrate a method for fabricating a package structure at various intermediate stages according to some embodiments of the present disclosure.

FIGS. 10-20 illustrate a method for fabricating an integrated circuit package structure at various intermediate stages according to some embodiments of the present disclosure.

FIG. 21A is an ion beam image of a cross-sectional view of a nanotwinned copper conductive feature according to some embodiments of the present disclosure.

FIG. 21B is an electron backscatter diffraction (EBSD) map of a plan view of a nanotwinned copper conductive feature according to some embodiments of the present disclosure.

FIG. 22A is an image of a cross-sectional view of a nanotwinned copper conductive feature and a Sn layer thereon according to some embodiments of the present disclosure.

FIG. 22B is an image of a cross-sectional view of a nanotwinned copper conductive feature and a Pd layer thereon according to some embodiments of the present disclosure.

FIG. 22C is an image of a cross-sectional view of a nanotwinned copper conductive feature and an Ag layer thereon according to some embodiments of the present disclosure.

FIG. 23A is an electron beam image of a cross-sectional view of a nanotwinned copper conductive feature and a Sn layer thereon according to some embodiments of the present disclosure.

FIG. 23B is an ion beam image of a cross-sectional view of a nanotwinned copper conductive feature and a Sn layer thereon according to some embodiments of the present disclosure.

FIG. 24A is an electron beam image of a cross-sectional view of a nanotwinned copper conductive feature and an Ag layer thereon according to some embodiments of the present disclosure.

FIG. 24B is an ion beam image of a cross-sectional view of a nanotwinned copper conductive feature and an Ag layer thereon according to some embodiments of the present disclosure.

FIG. 25A is an electron beam image of a cross-sectional view of a nanotwinned copper conductive feature and a thin Ag layer thereon according to some embodiments of the present disclosure.

FIG. 25B is an ion beam image of a cross-sectional view of a nanotwinned copper conductive feature and a thin Ag layer thereon according to some embodiments of the present disclosure.

FIG. 26A is an electron beam image of a cross-sectional view of a nanotwinned copper conductive feature and a thick Ag layer thereon according to some embodiments of the present disclosure.

FIG. 26B is an ion beam image of a cross-sectional view of a nanotwinned copper conductive feature and a thick Ag layer thereon according to some embodiments of the present disclosure.

FIG. 27A is an electron beam image of a cross-sectional view of a nanotwinned copper conductive feature and a thick Ag layer thereon according to some embodiments of the present disclosure.

FIG. 27B is an ion beam image of a cross-sectional view of a nanotwinned copper conductive feature and a thick Ag layer thereon according to some embodiments of the present disclosure.

FIG. 28A is an electron beam image of a cross-sectional view of a nanotwinned copper conductive feature and a thin Ag layer thereon after an annealing process according to some embodiments of the present disclosure.

FIG. 28B is energy-dispersive X-ray spectroscopy (EDS) result of a package structure shown in FIG. 28A.

FIG. 29A is an electron beam image of a cross-sectional view of a nanotwinned copper conductive feature and a thick Ag layer thereon after an annealing process according to some embodiments of the present disclosure.

FIG. 29B is energy-dispersive X-ray spectroscopy (EDS) result of a package structure shown in FIG. 29A.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

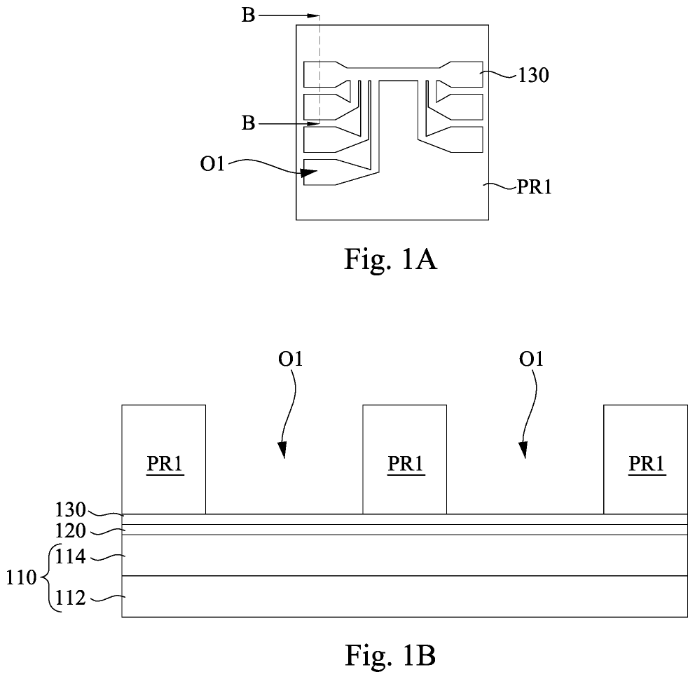

FIGS. 1A-5 illustrate a method for forming a package structure at various intermediate stages of manufacture according to some embodiments of the present disclosure. FIGS. 1A, 2A, 3A, and 4A are top views of the package structure according to some embodiments of the present disclosure. FIGS. 1B, 2B, 3B, 4B, and 5 are cross-sectional views of the package structure (e.g., taken along line B-B in FIGS. 1A, 2A, 3A, and 4A) according to some embodiments of the present disclosure. It is understood that additional steps may be provided before, during, and after the steps shown by FIGS. 1A-5, and some of the steps described below can be replaced or eliminated for additional embodiments of the method. The order of the operations/processes may be interchangeable.

Reference is made to FIGS. 1A and 1B. A semiconductor structure 110 is provided. The semiconductor structure 110 may comprises a main body 112 and an interconnect structure 114 over the main body 112. The main body 112 of the semiconductor structure 110 may comprise any number of substrates, transistors, active devices, passive devices, or the like. In some embodiments, the main body 112 may include a bulk semiconductor substrate, semiconductor-on-insulator (SOI) substrate, multi-layered semiconductor substrate, or the like. The semiconductor material of the main body 112 may be silicon, germanium, a compound semiconductor including silicon germanium, silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. The main body 112 may be doped or undoped. Devices, such as transistors, capacitors, resistors, diodes, and the like, may be formed in and/or on an active surface of the main body. An interconnect structure 114 comprising one or more dielectric layer(s) and respective metallization pattern(s) is formed on the active surface of the main body. The metallization pattern(s) in the dielectric layer(s) may route electrical signals between the devices, such as by using vias and/or traces, and may also contain various electrical devices, such as capacitors, resistors, inductors, or the like. The various devices and metallization patterns may be interconnected to perform one or more functions. The functions may include memory structures, processing structures, sensors, amplifiers, power distribution, input/output circuitry, or the like.

A seed layer 130 is formed over the semiconductor structure 110, in accordance with some embodiments. The seed layer 130 may include copper, titanium, combinations thereof, or another suitable conductive material. In some embodiments, the seed layer 130 is a <111>-oriented Cu seed layer formed by suitable electroplated process. For example, the seed layer 130 may have a (111) surface 130T. A thickness of the seed layer 130 may be in a range from about 150 nanometers to about 250 nanometers. In some embodiments, prior to the formation of the seed layer 130, a metal adhesive layer 120 is formed over the semiconductor structure 110. The metal adhesive layer 120 may include suitable conductive metal (e.g., titanium or titanium copper), which provides a good adhesion to the semiconductor structure 110. A thickness of the metal adhesive layer 120 may be in a range from about 50 nanometers to about 150 nanometers. In some embodiments, the thickness of the seed layer 130 may be greater than the thickness of the metal adhesive layer 120.

A patterned mask layer PR1 is formed over the seed layer 130, in accordance with some embodiments. The mask layer PR1 may include a photoresist material with through holes O1 formed by a lithography process. The through holes O1 in the patterned mask layer PR1 may expose portions of the seed layer 130, in accordance with some embodiments.

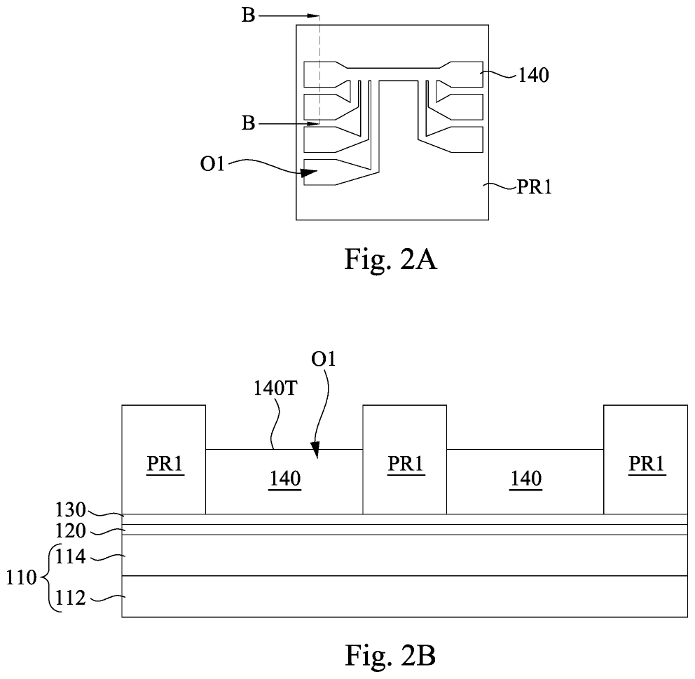

Reference is made to FIGS. 2A and 2B. A conductive layer 140 is electroplated on the (111) surface 130T of the seed layer 130 exposed by the opening O1. The conductive layer 140 is substantially made of highly-textured <111> twinned copper, in accordance with some embodiments. The twinned copper is also referred to as nano-twinned copper or nano-twin crystal copper. The term of twin in materials represents two crystals with a mirror symmetry relationship, in accordance with some embodiments. In some embodiments, the term “substantially made of” means that an average twinned copper volume percentage in the entire conductive layer 140 is greater than 90 vol %. That is, an average non-twinned copper volume percentage in the entire conductive layer 140 is less than 10 vol %. In some embodiments, the average twinned copper volume percentage in the entire conductive layer 140 ranges from about 95 vol % to about 99.9 vol %. The twinned copper includes (111)-oriented twinned copper, in accordance with some embodiments. The top surface 140T of the conductive layer 140 is a (111) surface, which has a relative high diffusion rate as well as a relative low surface energy, and a face-centered cubic (FCC) close-packed surface. The electroplating apparatus for the highly-textured <111> twinned copper is compatible with 3D integrated circuit (IC) fabrication process.

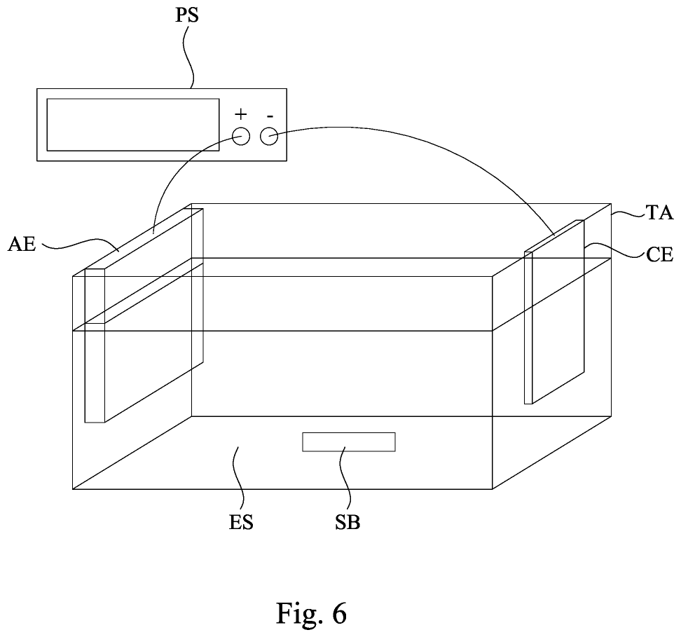

Formation of the conductive layer 140 includes performing an electroplating process (e.g., direct current electroplating process) on the seed layer 130 to form the conductive layer 140, in accordance with some embodiments. The electroplating process may also be referred to as an electro-chemical plating (ECP) process. FIG. 6 is a schematic view of an electroplating apparatus, in accordance with some embodiments. An electroplating solution ES including copper sulfate pentahydrate powder, sulfuric acid (e.g., at concentrations of 93% to 99%), hydrochloric acid (e.g., at concentrations of 35% to 40%), suitable additives, methyl sulfonate, and/or chlorine ion may be used during the direct current electroplating process. For example, copper sulfate pentahydrate powder (e.g., 180 g/L to 210 g/L), sulfuric acid (e.g., about 80 g/L to about 120 g/L), and hydrochloric acid (e.g., about 0.05 mL to about 1.5 mL), and deionized water are mixed and stirred to be uniform by a stir bar. Recipes of the electroplating solution ES is controlled such that the copper material are grown as twinned copper with (111) surface. The electroplating solution ES is poured into an electroplating tank TA, and a stir bar SB may be put in the electroplating tank TA. The stir bar SB may rotate at about 1000 rpm to about 1500 rpm during the direct current electroplating process at 1 atm. The electroplating process uses an anode AE and a cathode CE. In electroplating, the metal dissolved from the anode AE can be plated onto the cathode CE. The anode AE is provided with direct current introduced from an external power source PS, oxidizing and dissolving its metal atoms in the electrolyte solution ES. At the cathode CE, the dissolved metal ions are decreased and the metal is placed on the product (e.g., the semiconductor structure 110). Through the electroplating apparatus in FIG. 6, referring back to FIGS. 2A and 2B, the conductive layer 140 can be formed in direct contact with the seed layer 130. In some embodiments, the conductive layer 140 conformally covers the seed layer 130 exposed by the opening O1. In the context, the conductive layer 140 may also be referred to as a conductive feature 140, a conductive wire 140, or a conducive pad 140. In some embodiments, the conductive layer 140 may also be referred to as a copper feature 140.

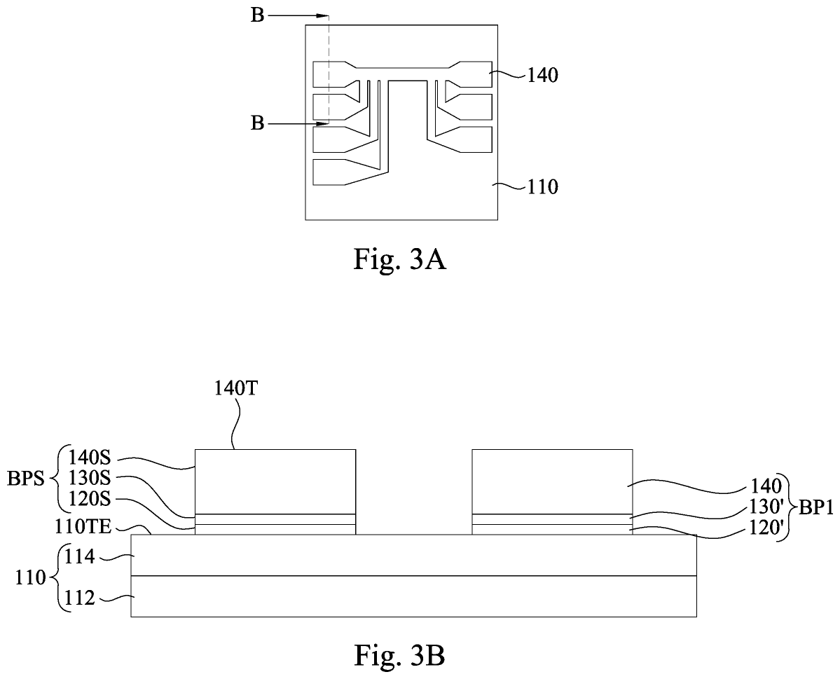

Reference is made to FIGS. 3A and 3B. After the electroplating process, the mask layer PR1 (referring to FIGS. 2A and 2B) is removed by suitable stripping process, followed by etching away a first portion of the seed layer 130 and a first portion of the metal adhesive layer 120 uncovered by the conductive layer 140. The conductive layer 140 may have a higher etch resistance to the etching process than that of the seed layer 130 and the metal adhesive layer 120, and can protect an underlying second portion of the seed layer 130 and an underlying second portion of the metal adhesive layer 120 from being etched. After the etching process, the second portions of the metal adhesive layer 120 and the seed layer 130 covered by the conductive layer 140 remain and are referred to as a metal adhesive layer 120′ and a seed layer 130′ hereinafter. Referring to FIG. 3B, a combination of the metal adhesive layer 120′, the seed layer 130′, and the conductive layer 140 forms a conductive structure BP1. In some embodiments of the present disclosure, a copper-first process is performed as illustrated in FIGS. 1A-3B. After the formation of the conductive structure BP1, a portion 100TE of the top surface of the semiconductor structure 110 is exposed by the conductive structure BP1.

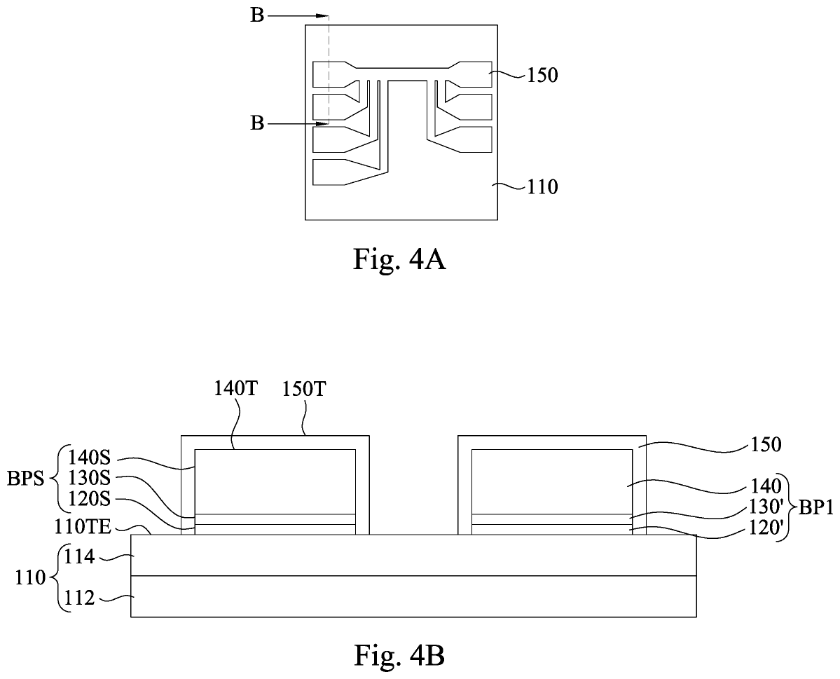

Reference is made to FIGS. 4A and 4B. After the formation of the conductive structure BP1, a metal cap layer 150 is selectively plated over the top surface of the conductive structure BP (e.g., the top surface 140T) and sidewalls BPS of the conductive structure BP1 (including sidewalls 140S of the conductive layer 140, sidewalls 130S of the seed layer 130, and sidewalls 120S of the metal adhesive layer 120). The metal cap layer 150 can include tin (Sn), noble metals (e.g., silver (Ag), gold (Au), or palladium (Pd)), the like, or the combination thereof. A metal material of the metal cap layer 150 may be different from that of the conductive layer 140. The metal cap layer 150 can be formed by suitable selective plating process, such as electroless plating, immersion plating process, the like, or the combination thereof. By the selective plating processes, an amount of the plated metal material directly on the top surface 140T of the conductive structure BP1 is greater than an amount of the plated metal material directly on the exposed portion 100TE of the top surface of the semiconductor structure 110 (or the interconnect structure 114). In some embodiments, no metal material is directly plated on the exposed portion 100TE of the top surface of the semiconductor structure 110. As a result, a metal cap layer 150 over a conductive structure BP1 is disconnected from another metal cap layer 150 over another conductive structure BP1. The metal cap layers 150 may serve as passivation layers block moisture and oxygen from reaching the conductive layers 140, thereby protecting the conductive layers 140 from oxidation.

In some embodiments, the recipe/compositions of the electroless-plating or immersion-plating solution used in the selective deposition process is selected such that the growth of the metal cap layer 150 may follow the crystal growth orientation of the conductive structure BP1. As a result, a portion or an entirety of the metal cap layer 150 may have highly-textured <111> twinned metal. The metal cap layer 150 may include the nano-twin crystal structure. This electroless-plating or immersion-plating solution forming the highly-textured <111> twinned metal may be referred to as first plating solution in the context. For example, the metal cap layer 150 may include nano-twinned metal, such as nano-twinned silver. The twinned silver includes (111)-oriented twinned silver, in accordance with some embodiments. The top surface 150T of the metal cap layer 150 is a (111) surface, which has a relative high diffusion rate as well as a relative low surface energy, and a face-centered cubic (FCC) close-packed surface.

Electroless plating involves the use of a plating bath without the imposition of any electric current where the substrate is plated by reduction of the plating metal from a solution of a salt of a plating metal. The plating solution contains controlled reducing agents which are either catalyzed by the surface of the substrate, or by some catalytic metal emplaced onto the surface both to initiate the reduction and to give good adherence. Since the plated-on surface is autocatalytic, an electroless process can be used to build up good thicknesses. Electroless plating can also be referred to as chemical plating or auto-catalytic plating. Electroless plating is a non-galvanic plating method that involves several simultaneous reactions in an aqueous solution, which occur without the use of external electrical power. The reaction is accomplished when hydrogen is released by a reducing agent, normally sodium hypophosphite (the hydrogen leaves as a hydride ion), and oxidized, thus producing a negative charge on the surface of the part. Furthermore, since an electroless process is not dependent upon current densities, the resulting coating is of excellent uniformity. Because electroless plating allows a consistant metal ion concentration to bathe all parts of the object, it deposits metal evenly along edges, inside holes and over irregularly shaped objects which are difficult to plate evenly with electroplating.

Immersion plating, like electroless plating, does not employ an electric current. Immersion plating, sometimes called galvanic plating, is an electrochemical displacement reaction which depends on the position that the substrate metal occupies in the electromotive series with respect to the metal to be deposited from solution. Plating occurs when the metal from a dissolved metal salt is displaced by a coating metal that is immersed in the solution. Immersion plating is the process of applying adhering layers of coating metals to another metal's surface by dipping in a coating metal solution ions to produce a replacement reaction. It causes the deposition of a metallic coating on a base metal from solutions that contain coating metal. In this, one metal is displaced by coating metal ions, which have different levels of oxidation potential from the metal ion being displaced. Immersion plating is also referred to as metal replacement and dip plating. Immersion plating is distinct from various electroplating processes in the sense that there is no presence of external current. This process follows the principle: when metal components such as copper are put into an electrolyte with more coating metal ions, the copper will undergo dissolution. This, in turn results in the release of electrons, allowing coating metals to settle down. Unlike with electro-less plating, the deposition of metals is halted once the plated object is completely coated with the coating metals.

In some embodiments, prior to the selective plating processes, the semiconductor structure 110 and the conductive structure BP1 may be cleaned with an organic agent (e.g., acetone) that remove oils and dust thereon, washed by deionized water to remove residues, and slightly etched by organic acids (e.g., citric acid) for removing native oxides from the conductive structure BP1. The semiconductor structure 110 and the conductive structure BP1 may be washed by deionized water after using the organic acids (e.g., citric acid) to remove the native oxides and prior to selectively plating the metal cap layer 150 over the conductive structure BP1.

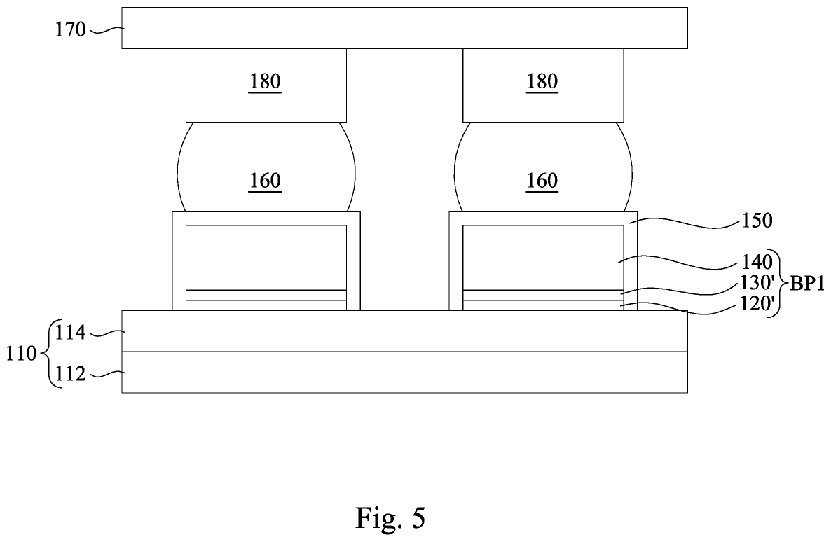

Reference is made to FIG. 5. The semiconductor structure 110 is bonded with a work piece (e.g., another semiconductor structure, such as the substrate 170). In some embodiments, a connector 160 may be formed over the metal cap layer 150. In some examples, the connectors 160 may be solder balls including a solder material in some embodiments. In some alternative embodiments, the connectors 160 may be metal pillars, controlled collapse chip connection (C4) bumps, micro bumps, the like, or the combination thereof. The connector 160 may include a conductive material such as solder, copper, aluminum, gold, nickel, silver, palladium, tin, the like, or a combination thereof. The connector 160 bonds the metal cap layer 150 over the conductive structure BP1 to a conductive structure 180 (also referred to as a bond pad) over another substrate 170.

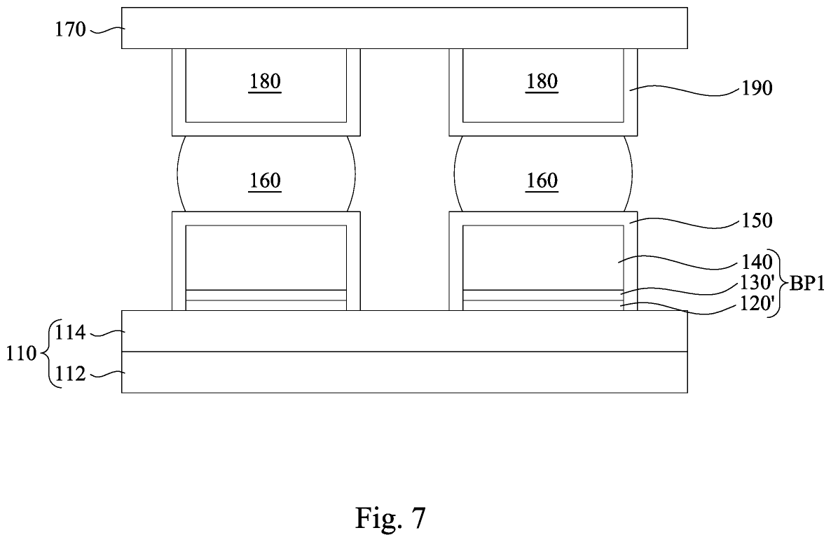

FIG. 7 is a cross-sectional view of a package structure according to some embodiments of the present disclosure. The conductive structure 180 over another substrate 170 is selectively plated with a metal cap layer 190. The connector 160 bonds the metal cap layer 150 over the conductive structure BPI to the metal cap layer 190 over the conductive structure 180. Formation and details of the conductive structure 180 and the metal cap layer 190 may be similar to the conductive structure 140 and the metal cap layer 150 mentioned above, and thereto not repeated herein.

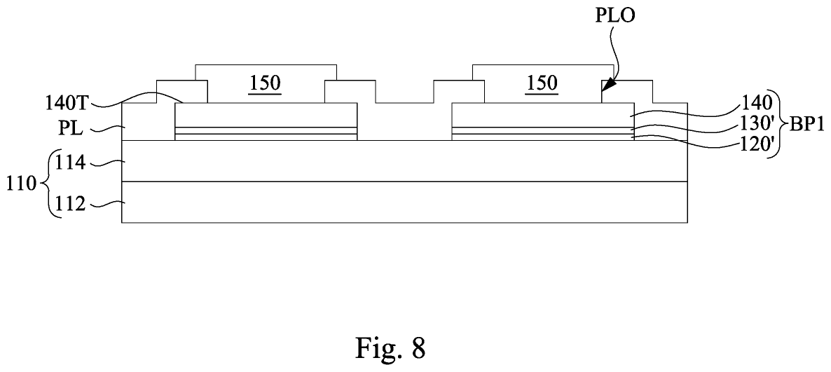

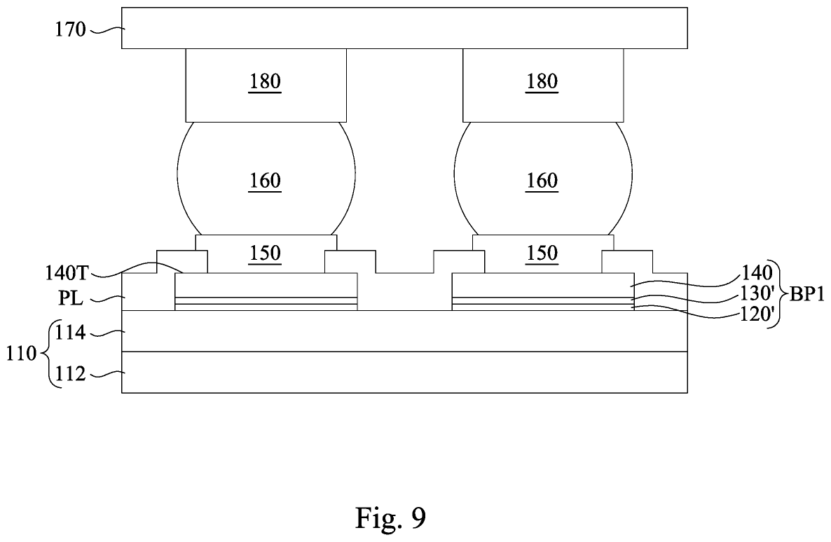

FIGS. 8 and 9 illustrate a method for fabricating a package structure at various intermediate stages according to some embodiments of the present disclosure. Details of the present embodiments are similar to those of FIGS. 1A-5, except that a passivation layer PL is formed over the conductive feature BPI prior to the formation of the metal cap layer 150. The conductive feature BP1 with the metal cap layer 150 can be used in a front side metallization for metal-oxide-semiconductor field-effect transistor (MOSFET). For example, the conductive feature BP1 may serve as a redistribution line over the interconnect structure 114.

Reference is made to FIG. 8. The passivation layer PL is formed over the conductive feature BP1 and the semiconductor structure 110, and the passivation layer PL has an opening PLO directly over the conductive feature BPI to expose the top surface of the conductive feature BP1. As aforementioned, the conductive feature BP1 includes the metal adhesive layer 120′, the seed layer 130′, and the nanotwinned copper conductive layer 140, and the top surface of the conductive feature BPI exposed by the passivation layer PL is the top surface 140T of the nanotwinned copper conductive layer 140.

In some embodiments, the passivation layer PL is an organic material, such as, polyimide, polybenzoxazole (PBO), and benzocyclobutene (BCB), formed by suitable coating process, followed by a soft baking process and a hard baking process. In some embodiments, the passivation layer PL is an inorganic material, such as silicon nitride, silicon oxide, silicon oxynitride, the like, or the combination thereof, formed by suitable deposition process, such as chemical vapor deposition (CVD) or atomic layer deposition (ALD). In some embodiments, the passivation layer PL is a photoresist material having the opening PLO by photolithography process. The photolithography process may include coating a photoresist layer (not shown), exposing the photoresist layer to a pattern, performing post-exposure bake processes, and developing the photoresist layer to form the passivation layer PL. In some other embodiments, the passivation layer PL is patterned by suitable etching, thereby having the opening PLO to expose the top surface of the conductive feature BP1. In some alternative embodiments, a portion of the passivation layer PL is removed by a planarization process (e.g., chemical mechanical polish (CMP) process), and a remaining portion of the passivation layer PL may expose the top surface of the conductive feature BP1.

The metal cap layer 150 selectively plated over the exposed top surface of the conductive feature BP1. The metal cap layer 150 may serve as under-bump metallurgies (UBMs) for external connection to the redistribution line (e.g., the conductive feature BP1). By the selective plating processes, an amount of the plated metal material directly on the top surface 140T of the conductive structure BP1 is greater than an amount of the plated metal material directly on the passivation layer PL, which is uncovered by the conductive feature BP1. In some embodiments, no metal material is directly plated on the passivation layer PL, such that a top surface of the passivation layer PL is free from a metal material of the metal cap layer 150.

Reference is made to FIG. 9. The semiconductor structure 110 is bonded with a work piece. In some embodiments, a connector 160 may be formed over the metal cap layer 150. The connector 160 may include a solder material in some embodiments. The connector 160 bonds the metal cap layer 150 over the conductive structure BPI to a conductive structure 180 over another substrate 170.

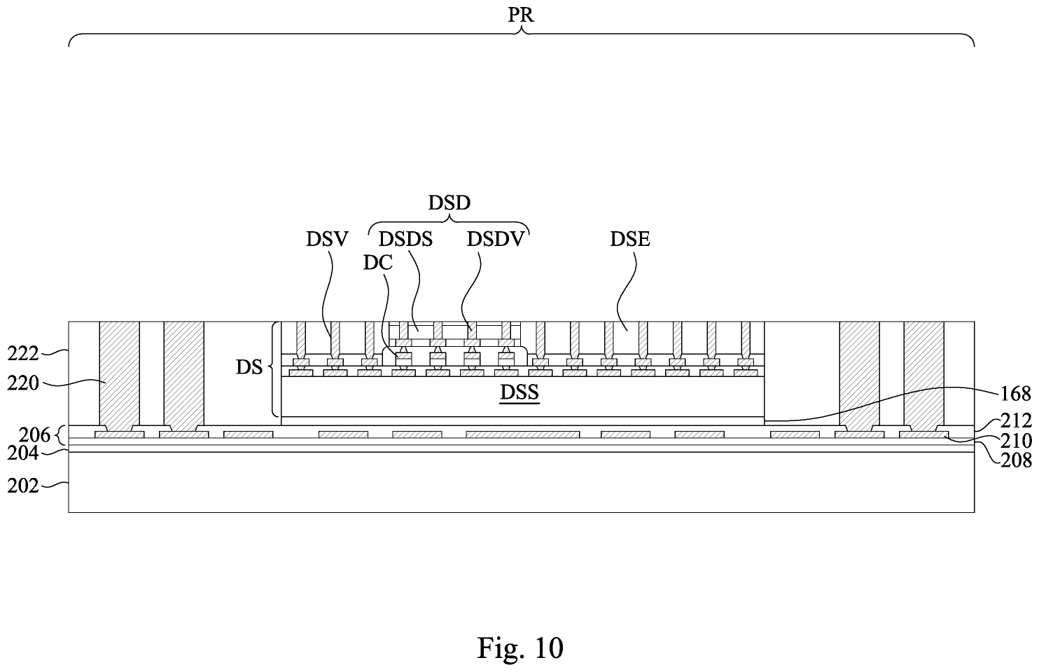

FIGS. 10-20 illustrate a method for fabricating an integrated circuit package structure at various intermediate stages according to some embodiments of the present disclosure. FIGS. 10-20 are cross-sectional views of the integrated circuit package structure according to some embodiments of the present disclosure. It is understood that additional steps may be provided before, during, and after the steps shown by FIGS. 10-20, and some of the steps described below can be replaced or eliminated for additional embodiments of the method. The order of the operations/processes may be interchangeable. A die stack DS is packaged in an integrated circuit package 200. Packaging of devices in one package region PR is illustrated, but it should be appreciated that any number of package regions may be simultaneously formed. The package region PR will be singulated in subsequent processing. The singulated integrated circuit package 200 may be a fan-out package, such as an integrated fan-out (InFO) package. The singulated integrated circuit package 200 is then mounted to a target device (e.g., package substrate 400) to form a completed system.

Reference is made to FIG. 10. A carrier substrate 202 is provided, and a release layer 204 is formed on the carrier substrate 202. The carrier substrate 202 may be a glass carrier substrate, a ceramic carrier substrate, or the like. The carrier substrate 202 may be a wafer, such that multiple packages can be formed on the carrier substrate 202 simultaneously. The release layer 204 may be formed of a polymer-based material, which may be removed along with the carrier substrate 202 from the overlying structures that will be formed in subsequent steps. A back-side redistribution structure 206 can optionally be formed on the release layer 204. In the embodiment shown, the back-side redistribution structure 206 includes a dielectric layer 208, a metallization pattern 210 (sometimes referred to as redistribution layers or redistribution lines), and a dielectric layer 212. The back-side redistribution structure 206 may include any number of dielectric layers and metallization patterns. The metallization patterns may include conductive lines and conductive vias. The conductive vias may therefore interconnect and electrically couple the various conductive lines. In some embodiments, the back-side redistribution structure 206 is optional. In some embodiments, a dielectric layer without metallization patterns is formed on the release layer 204 in lieu of the back-side redistribution structure 206.

Conductive vias 220 are formed extending through the topmost dielectric layer of the back-side redistribution structure 206 (e.g., the dielectric layer 212), and away from the carrier substrate 202. The conductive vias 220 are connected to the topmost metallization pattern of the back-side redistribution structure 206 (e.g., the metallization pattern 210). In some embodiments, the conductive vias 220 are optional, and may be omitted. As an example to form the conductive vias 220, the dielectric layer 212 can be patterned to form openings exposing portions of the metallization pattern 210. The conductive vias 220 can be formed over the exposing portions of the metallization pattern 210.

A singulated die stack DS is then placed adjacent the conductive vias 220. The die stack DS can be placed on the back-side redistribution structure 206 (e.g., the dielectric layer 212) when the back-side redistribution structure 206 is formed, or can be placed on the release layer 204 when the back-side redistribution structure 206 is omitted. The adhesive 168 is used to adhere the singulated die stack DS to the underlying layer (e.g., the dielectric layer 212 or the release layer 204). The die stack DS may be a package structure including a semiconductor substrate DSS, conductive vias DSV, an integrated circuit die DSD including a semiconductor substrate DSDS and conductive vias DSDV, die connectors DC and an encapsulant DSE.

An encapsulant 222 is formed on and around the various components. After formation, the encapsulant 222 encapsulates the conductive vias 220 and the die stack DS. The encapsulant 222 may be a molding compound, epoxy, or the like. The encapsulant 222 may be applied by compression molding, transfer molding, or the like, and is formed over the carrier substrate 202 such that the conductive vias 220 and/or the die stack DS are buried or covered. The encapsulant 222 may be applied in liquid or semi-liquid form and then subsequently cured. After the formation of the encapsulant 222, a planarization process can be performed on the encapsulant 222 and die stack DS to expose the conductive vias DSV, DSDV and 220.

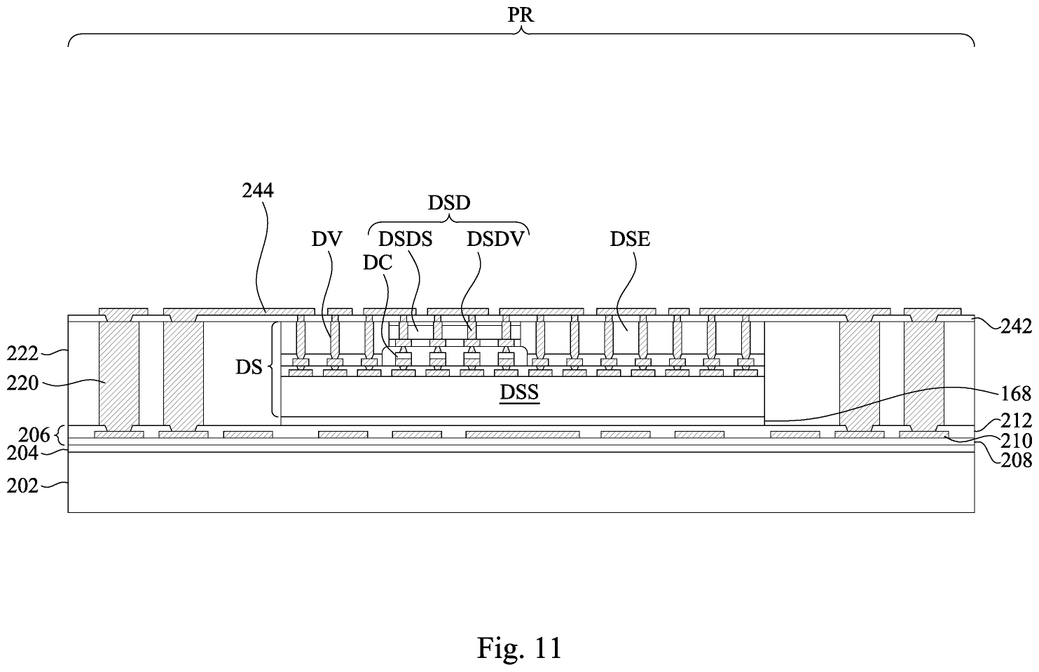

FIGS. 11-15 shows the formation of a front-side redistribution structure 240 over the encapsulant 222, conductive vias 220, and die stack DS. The front-side redistribution structure 240 includes dielectric layers 242, 246, 250, 254 and metallization patterns 244, 248, 252. The metallization patterns may also be referred to as redistribution layers or redistribution lines. The front-side redistribution structure 240 is shown as an example having three layers of metallization patterns. More or fewer dielectric layers and metallization patterns may be formed in the front-side redistribution structure 240. If fewer dielectric layers and metallization patterns are to be formed, steps and process discussed below may be omitted. If more dielectric layers and metallization patterns are to be formed, steps and processes discussed below may be repeated.

Reference is made to FIG. 11. The dielectric layer 242 can be deposited on the encapsulant 222, conductive vias 220, and die stack DS. The barrier layer 224 thus contacts the dielectric layer 242. In some embodiments, the dielectric layer 242 is formed of a photo-sensitive material such as PBO, polyimide, BCB, or the like, which may be patterned using a lithography mask. The dielectric layer 242 may be formed by spin coating, lamination, CVD, the like, or a combination thereof. The dielectric layer 242 is then patterned. The patterning forms openings exposing portions of the conductive vias DSV, DSDV and 220. The patterning may be by an acceptable process, such as by exposing the dielectric layer 242 to light when the dielectric layer 242 is a photo-sensitive material or by etching using, for example, an anisotropic etch. If the dielectric layer 242 is a photo-sensitive material, the dielectric layer 242 can be developed after the exposure.

The metallization pattern 244 is then formed. The metallization pattern 244 includes line portions (also referred to as conductive lines) on and extending along the major surface of the dielectric layer 242. The metallization pattern 244 may further includes via portions (also referred to as conductive vias) extending through the dielectric layer 242 to be connected to the conductive vias DSV, DSDV and 220. As an example to form the metallization pattern 244, a seed layer is formed over the dielectric layer 242 and in the openings extending through the dielectric layer 242. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using, for example, PVD or the like. A photoresist is then formed and patterned on the seed layer. The photoresist may be formed by spin coating or the like and may be exposed to light for patterning. The pattern of the photoresist corresponds to the metallization pattern 244. The patterning forms openings through the photoresist to expose the seed layer. A conductive material is then formed in the openings of the photoresist and on the exposed portions of the seed layer. The conductive material may be formed by plating, such as electroplating or electroless plating, or the like. The conductive material may comprise a metal, like copper, titanium, tungsten, aluminum, or the like. In some embodiments, the conductive material includes nanotwinned copper. The combination of the conductive material and underlying portions of the seed layer form the metallization pattern 244. The photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process, such as by wet or dry etching.

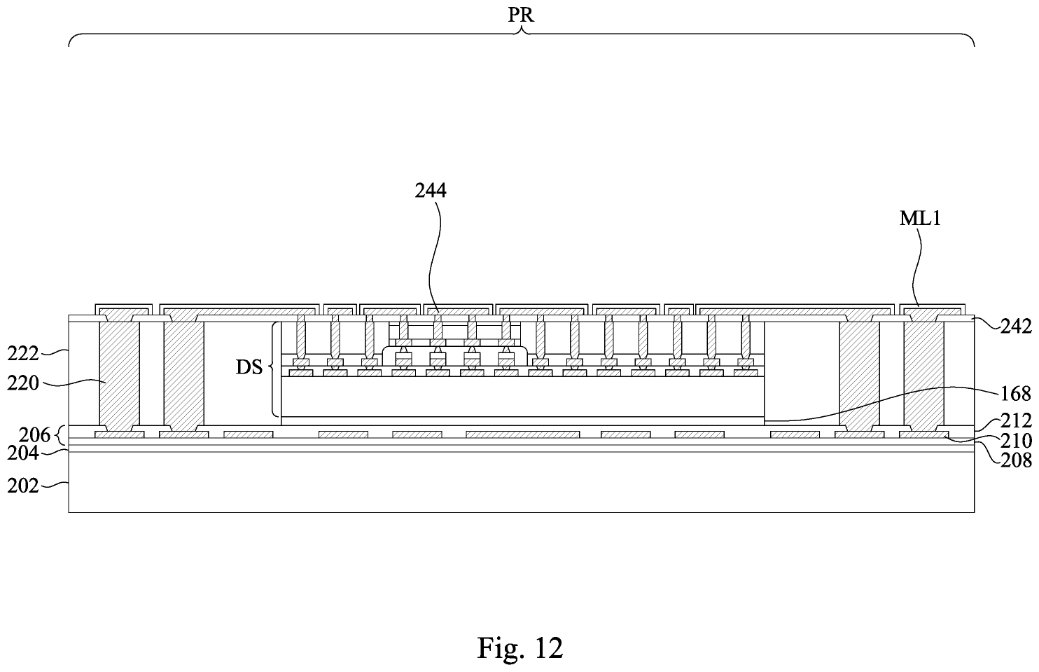

Reference is made to FIG. 12. A metal cap layers ML1 are formed over the metallization pattern 244. The metal cap layers ML1 is selectively plated over the top surface and sidewalls of the line portions of the metallization pattern 244. The major surface of the dielectric layer 242 away from the line portions of the metallization pattern 244 may be free of materials of the metal cap layers ML1. Formation of the metal cap layers ML1 is similar to the formation of the metal cap layer 150 (referring to FIGS. 4A and 4B), and thereto not repeated herein.

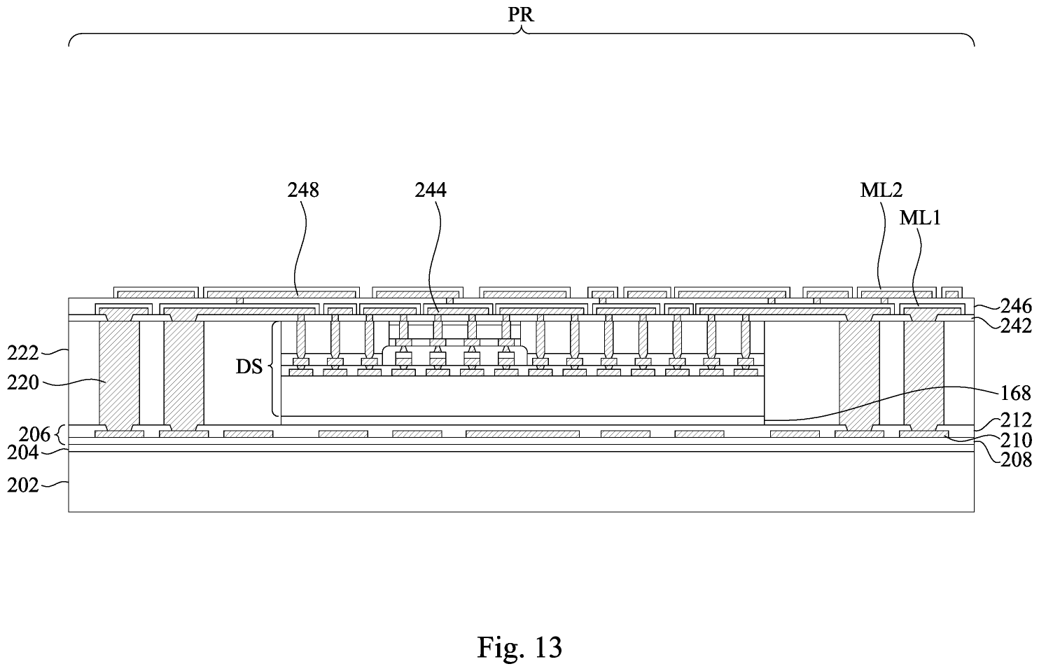

Reference is made to FIG. 13. The dielectric layer 246 is then deposited on the metal cap layer ML1 and dielectric layer 242. The dielectric layer 246 can be formed in a similar manner and of similar materials as the dielectric layer 242. The metallization pattern 248 is then formed. The metallization pattern 248 includes line portions on and extending along the major surface of the dielectric layer 246. The metallization pattern 248 further includes via portions extending through the dielectric layer 246 to be connected to the metallization pattern 244. The metallization pattern 248 can be formed in a similar manner and of similar materials as the metallization pattern 244. A metal cap layers ML2 are formed over the metallization pattern 248 in a similar manner and of similar materials as the metal cap layer ML1. The metal cap layers ML2 is selectively plated over the top surface and sidewalls of the line portions of the metallization pattern 248. The major surface of the dielectric layer 246 away from the line portions of the metallization pattern 248 may be free of materials of the metal cap layers ML2. Formation of the metal cap layers ML2 is similar to the formation of the metal cap layer 150 (referring to FIGS. 4A and 4B), and thereto not repeated herein.

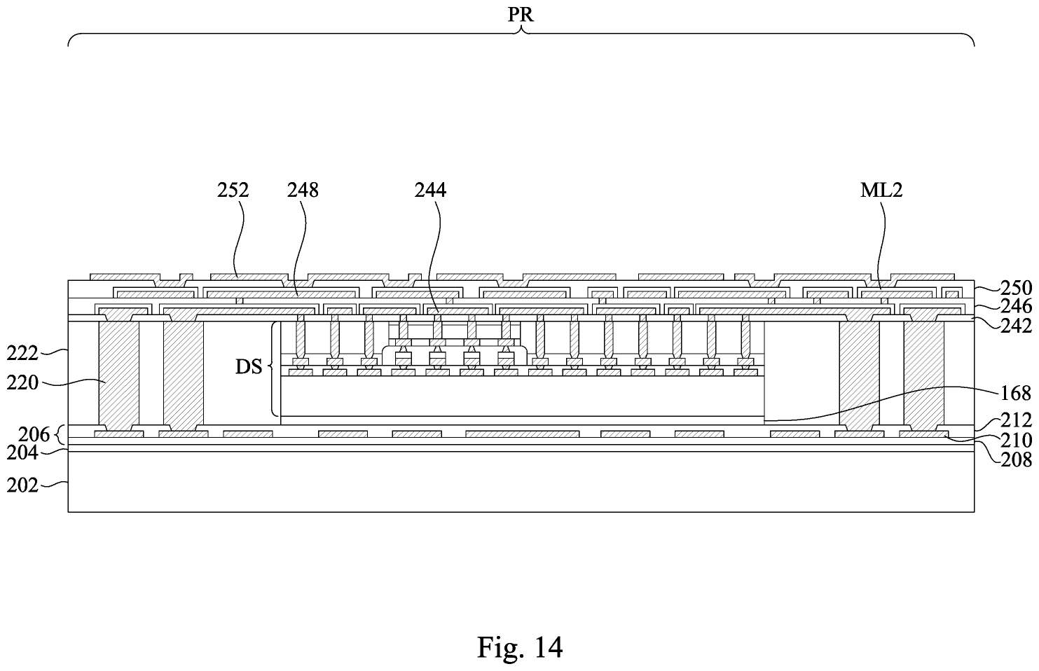

Reference is made to FIG. 14. The dielectric layer 250 is then deposited on the metal cap layers ML2 and dielectric layer 246. The dielectric layer 250 can be formed in a similar manner and of similar materials as the dielectric layer 242.

The metallization pattern 252 is then formed. The metallization pattern 252 includes line portions on and extending along the major surface of the dielectric layer 250. The metallization pattern 252 further includes via portions extending through the dielectric layer 250 to be connected to the metallization pattern 248. The metallization pattern 252 can be formed in a similar manner and of similar materials as the metallization pattern 244. The metallization pattern 252 is the topmost metallization pattern of the front-side redistribution structure 240. As such, all of the intermediate metallization patterns of the front-side redistribution structure 240 (e.g., the metallization patterns 244 and 248) are disposed between the metallization pattern 252 and the die stack DS.

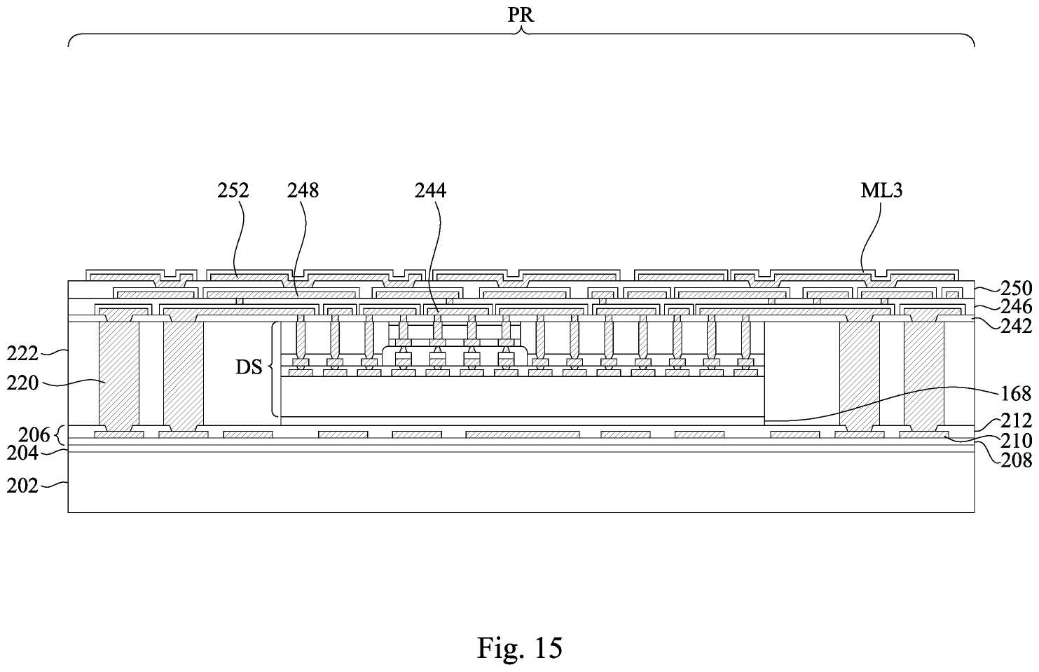

Reference is made to FIG. 15. The metal cap layers ML3 is selectively plated over the top surface and sidewalls of the line portions of the metallization pattern 252 and top surface of the via portions of the metallization pattern 252. The major surface of the dielectric layer 250 away from the line portions and the via portions of the metallization pattern 252 may be free of materials of the metal cap layers ML3. Formation of the metal cap layers ML3 is similar to the formation of the metal cap layer 150 (referring to FIGS. 4A and 4B), and thereto not repeated herein.

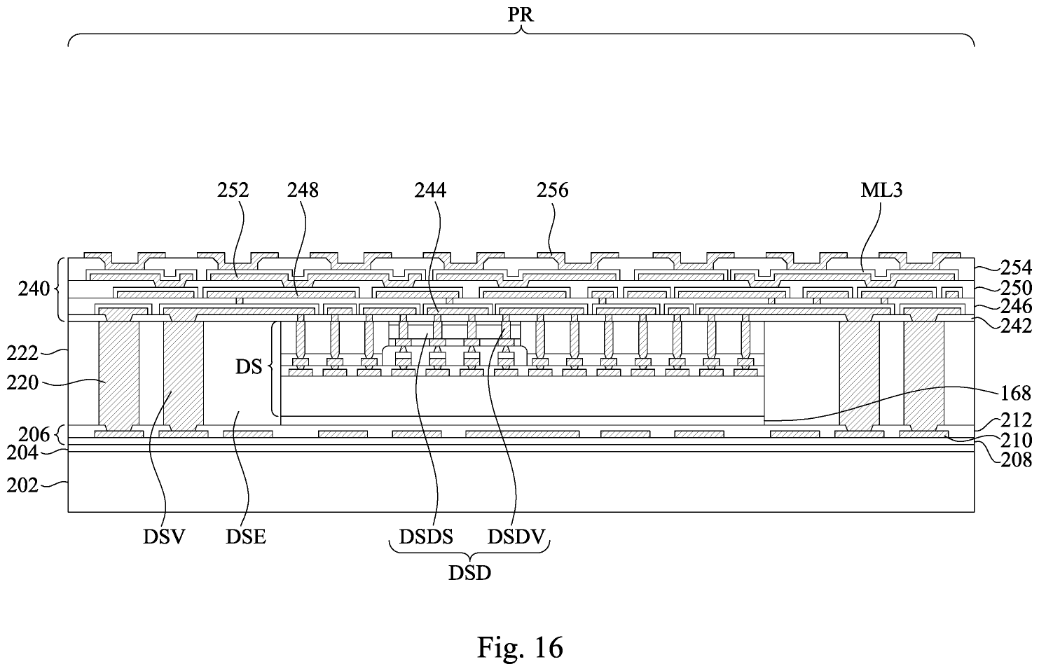

Reference is made to FIG. 16. The dielectric layer 254 is then deposited on the metal cap layers ML3 and dielectric layer 250. The dielectric layer 254 can be formed in a similar manner and of similar materials as the dielectric layer 242. UBMs 256 are formed for external connection to the front-side redistribution structure 240. The UBMs 256 have bump portions on and extending along the major surface of the dielectric layer 254, and have via portions extending through the dielectric layer 254 to be connected to the metallization pattern 252. As a result, the UBMs 256 are electrically coupled to the conductive vias DSV, DSDV and 220. The UBMs 256 may be formed of a similar material as the metallization pattern 244.

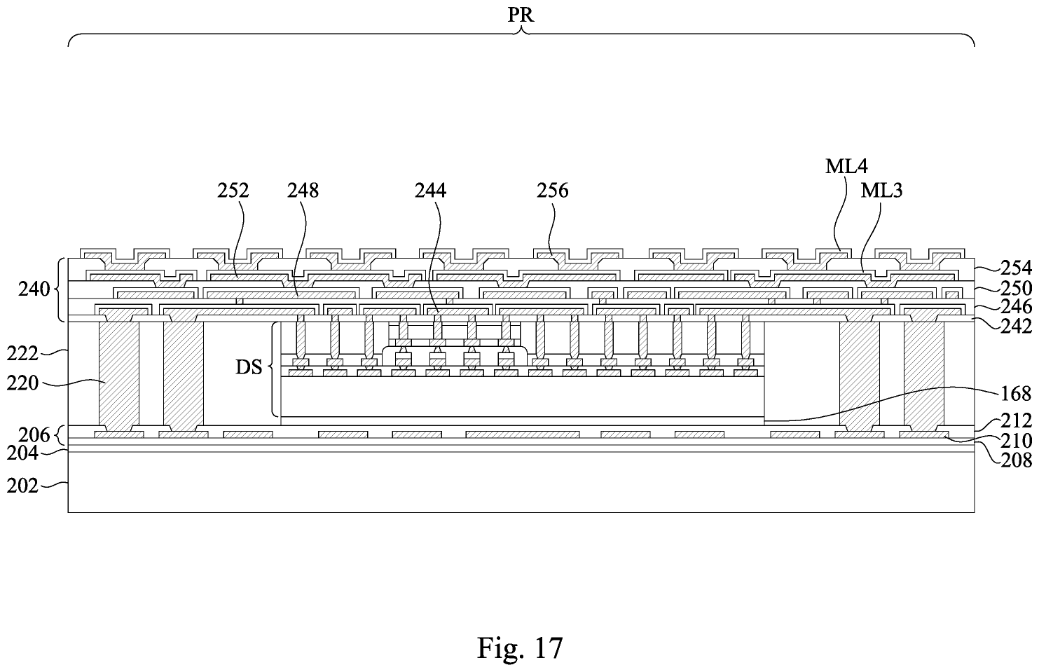

Reference is made to FIG. 17. The metal cap layers ML4 is selectively plated over the top surface and sidewalls of the bump portions of the UBMs 256 and top surface of the via portions of the UBMs 256. The major surface of the dielectric layer 254 away from the bump portions and the via portions of the UBMs 256 may be free of materials of the metal cap layers ML4. Formation of the metal cap layers ML4 is similar to the formation of the metal cap layer 150 (referring to FIGS. 4A and 4B), and thereto not repeated herein.

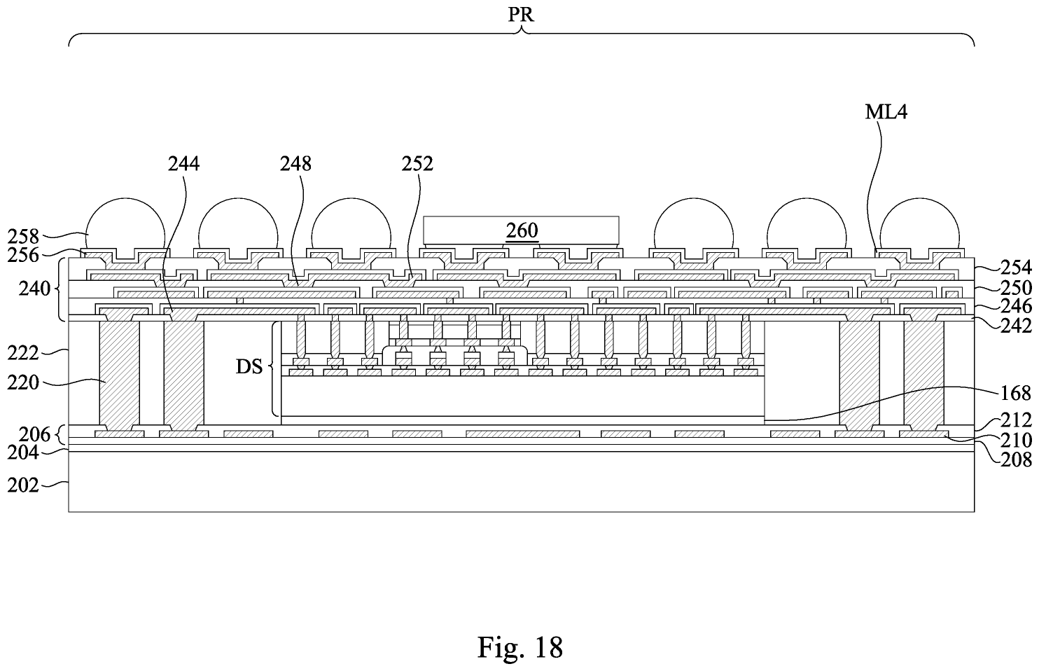

Reference is made to FIG. 18. Conductive connectors 258 are then formed on the UBMs 256 and the metal cap layers ML4. The conductive connectors 258 may be ball grid array (BGA) connectors, solder balls, metal pillars, controlled collapse chip connection (C4) bumps, micro bumps, or the like. The conductive connectors 258 may include a conductive material such as solder, copper, aluminum, gold, nickel, silver, palladium, tin, the like, or a combination thereof. In some embodiments, the conductive connectors 258 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiments, the conductive connectors 258 comprise metal pillars (such as a copper pillar) formed by a sputtering, printing, electro plating, electroless plating, CVD, or the like. The metal pillars may be solder free and have substantially vertical sidewalls.

One or more integrated passive devices (IPDs) 260 are optionally connected to the metal cap layers ML4 over the UBMs 256 with a subset of the conductive connectors 258. The IPDs 260 may be surface mount devices (SMDs), 2-terminal integrated passive devices (IPDs), multi-terminal IPDs, or other types of passive devices. The IPDs 260 can include a main structure and one or more passive devices in the main structure. The main structure can be, e.g., a semiconductor substrate, an encapsulant, or the like. The passive devices may include capacitors, resistors, inductors, the like, or a combination thereof, which can be formed in and/or on the main structure. The IPDs 260 can be connected to the metal cap layers ML4 over the UBMs 256 by reflowing the conductive connectors 258. In some embodiments, the IPDs 260 can be omitted. In some embodiments, an underfill (not shown) can be formed between the topmost dielectric layer of the front-side redistribution structure 240 (e.g., the dielectric layer 254) and each of the IPDs 260.

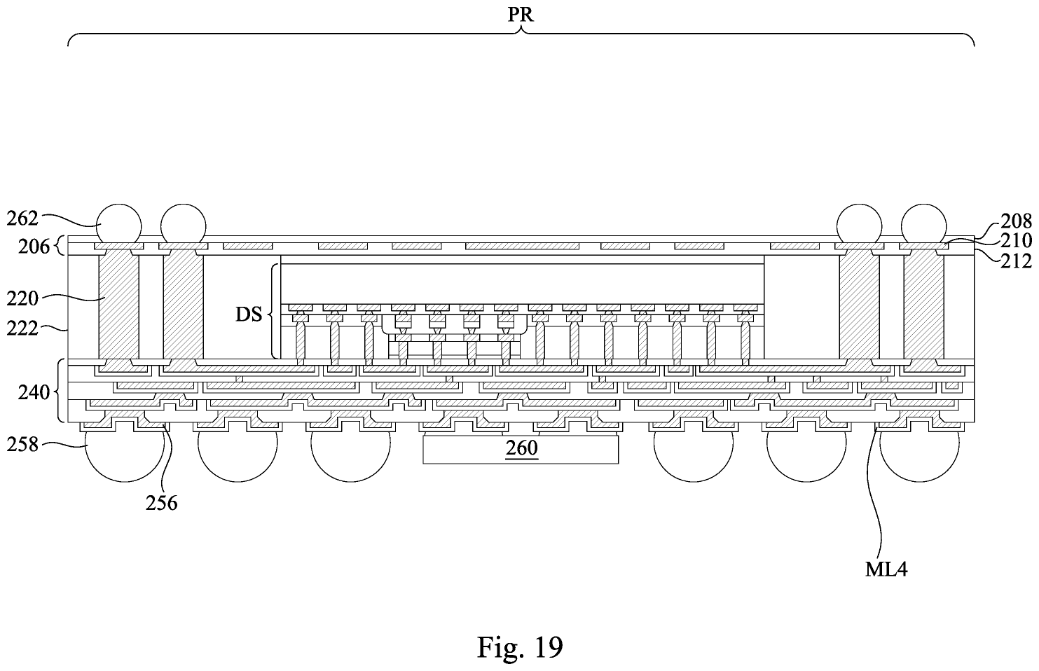

Reference is made to FIG. 19. A carrier substrate debonding is performed to detach (de-bond) the carrier substrate 202 (referring to FIG. 18) from the back-side redistribution structure 206, e.g., the dielectric layer 208. In accordance with some embodiments, the de-bonding includes projecting a light such as a laser light or an UV light on the release layer 204 so that the release layer 204 decomposes under the heat of the light and the carrier substrate 202 can be removed. The structure can then be flipped over and placed on, e.g., a tape. Further, conductive connectors 262 are formed through the dielectric layer 208 of the back-side redistribution structure 206. Openings can be formed through the dielectric layer 208 of the back-side redistribution structure 206, exposing portions of the metallization patterns 210. The openings may be formed, for example, using laser drilling, etching, or the like. The conductive connectors 262 are formed in the openings, and are connected to exposed portions of the metallization patterns 210. The conductive connectors 262 can be formed in a similar manner and of similar materials as the conductive connectors 258.

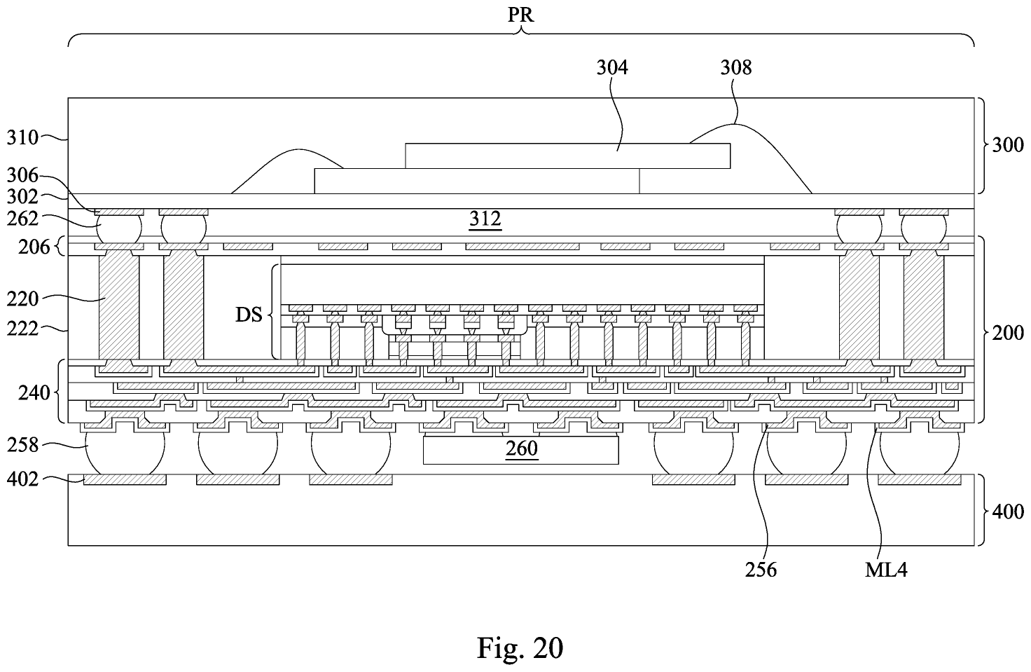

Reference is made to FIG. 20. A singulation process is performed by sawing along scribe line regions, e.g., around the package region PR. The singulation process includes sawing the redistribution structures 206, 240 and encapsulant 222. The singulation process separates the package region PR from adjacent package regions (not illustrated) to form an integrated circuit package 200.

Another integrated circuit package 300 can be attached to the integrated circuit package 200 to form a package-on-package structure. The integrated circuit package 300 may be a memory device. The integrated circuit package 300 can be attached to the integrated circuit package 200 before or after the integrated circuit package 200 is singulated.

The integrated circuit package 300 includes a substrate 302 and one or more dies 304 connected to the substrate 302. In some embodiments one or more stacks of dies 304 are connected to the substrate 302. The substrate 302 may be made of a semiconductor material such as silicon, germanium, diamond, or the like. In some embodiments, compound materials such as silicon germanium, silicon carbide, gallium arsenic, indium arsenide, indium phosphide, silicon germanium carbide, gallium arsenic phosphide, gallium indium phosphide, combinations of these, and the like, may also be used. Additionally, the substrate 302 may be a silicon-on-insulator (SOI) substrate. Generally, an SOI substrate includes a layer of a semiconductor material such as epitaxial silicon, germanium, silicon germanium, SOI, silicon germanium on insulator (SGOI), or combinations thereof. The substrate 302 is, in another embodiments, based on an insulating core such as a fiberglass reinforced resin core. One example core material is fiberglass resin such as FR4. Other core materials include bismaleimide-triazine (BT) resin, other printed circuit board (PCB) materials or films, or the like. Build up films such as Ajinomoto build-up film (ABF) or other laminates may be used for substrate 302. The substrate 302 may include active, passive devices, metallization layers (not shown), and/or through vias to form functional circuitry. In some embodiments, the substrate 302 is substantially free of active and passive devices. The substrate 302 may have bond pads 306 on a side the substrate 302, to connect to the conductive connectors 262. In some embodiments, the bond pads 306 are UBMs that include three layers of conductive materials, such as a layer of titanium, a layer of copper, and a layer of nickel.

In the illustrated embodiments, the dies 304 are connected to the substrate 302 by wire bonds 308, although other connections may be used, such as conductive bumps. In some embodiments, the dies 304 are stacked memory dies. The dies 304 and the wire bonds 308 (when present) may be encapsulated by a molding material 310. The molding material 310 may be molded on the dies 304 and the wire bonds 308, for example, using compression molding. In some embodiments, the molding material 310 is a molding compound, a polymer, an epoxy, silicon oxide filler material, the like, or a combination thereof. A curing process may be performed to cure the molding material 310; the curing process may be a thermal curing, a UV curing, the like, or a combination thereof.

After the integrated circuit package 300 is formed, the integrated circuit package 300 is attached to the integrated circuit package 200 by way of the conductive connectors 262. The conductive connectors 262 can be connected to the bond pads 306 by reflowing the conductive connectors 262. The dies 304 may thus be electrically coupled to the die stack DS through the conductive connectors 262, the conductive vias 220, and the redistribution structures 206, 240. In some embodiments, an underfill 312 is formed between the redistribution structure 206 and the substrate 302, and surrounding the conductive connectors 262. The underfill 312 may reduce stress and protect the joints resulting from the reflowing of the conductive connectors 262.

The integrated circuit package 200 is then attached to a package substrate 400 using the conductive connectors 258. The package substrate 400 may be made of a semiconductor material such as silicon, germanium, diamond, or the like. Alternatively, compound materials such as silicon germanium, silicon carbide, gallium arsenic, indium arsenide, indium phosphide, silicon germanium carbide, gallium arsenic phosphide, gallium indium phosphide, combinations of these, and the like, may also be used. Additionally, the package substrate 400 may be a SOI substrate. Generally, an SOI substrate includes a layer of a semiconductor material such as epitaxial silicon, germanium, silicon germanium, SOI, SGOI, or combinations thereof. The package substrate 400 is, in another embodiments, based on an insulating core such as a fiberglass reinforced resin core. One example core material is fiberglass resin such as FR4. Alternatives for the core material include bismaleimide-triazine (BT) resin, or alternatively, other printed circuit board (PCB) materials or films. Build up films such as Ajinomoto build-up film (ABF) or other laminates may be used for package substrate 400.

The package substrate 400 may include active and passive devices (not illustrated). Devices such as transistors, capacitors, resistors, combinations of these, and the like may be used to generate the structural and functional requirements of the design for the system. The devices may be formed using any suitable methods.

The package substrate 400 may also include metallization layers and vias (not illustrated) and bond pads 402 over the metallization layers and vias. The bond pads 402 may also be referred to as conductive features in some embodiments. The metallization layers may be formed over the active and passive devices and are designed to connect the various devices to form functional circuitry. The metallization layers may be formed of alternating layers of dielectric (e.g., low-k dielectric material) and conductive material (e.g., copper) with vias interconnecting the layers of conductive material and may be formed through any suitable process (such as deposition, damascene, dual damascene, or the like). In some embodiments, the package substrate 400 is substantially free of active and passive devices.

The conductive connectors 258 are reflowed to attach the metal cap layer ML4 over the UBMs 256 to the bond pads 402. The conductive connectors 258 connect the package substrate 400, including metallization layers in the package substrate 400, to the integrated circuit package 200, including metallization patterns of the redistribution structure 240. In some embodiments, an underfill (not illustrated) may be formed between the integrated circuit package 200 and the package substrate 400, surrounding the conductive connectors 258.

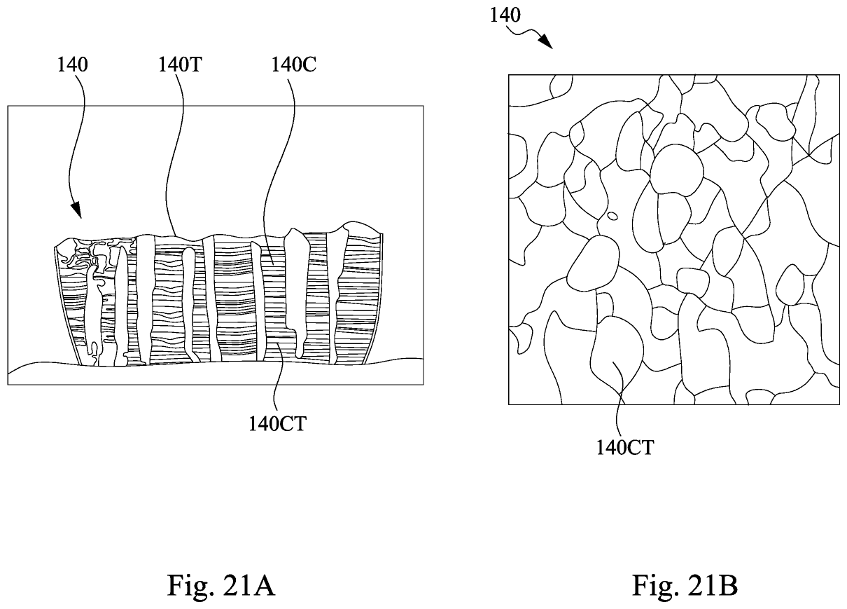

FIG. 21A is an ion beam image of a cross-sectional view of a nanotwinned copper conductive feature 140 according to some embodiments of the present disclosure. There are many column/cone structures 140C included in one nanotwinned copper conductive feature 140. Each of the column/cone structures 140C may include a nano-twinned crystal containing a plurality of coherent and incoherent twin boundaries 140CT. FIG. 21B is an electron backscatter diffraction (EBSD) map of a plan view of a nanotwinned copper conductive feature according to some embodiments of the present disclosure. Although not shown, the grains in FIG. 21B are in a distribution of blue and purple color, which indicates that the crystal is (111) oriented by more than 90%, for example, almost 99%. It is evidenced from FIGS. 21A and 21B that the electroplating process was used to fabricate highly (111)-oriented columnar crystal grains with densely-packed nano-twinned film.

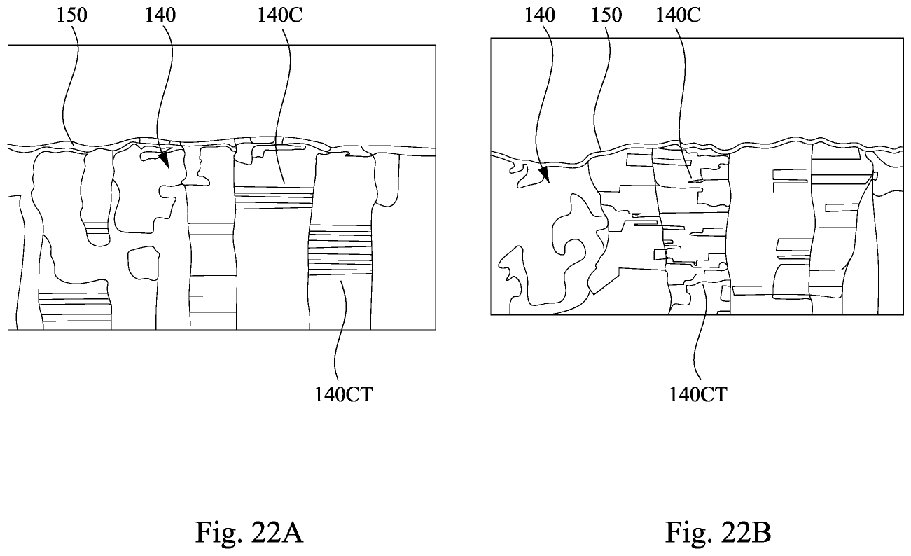

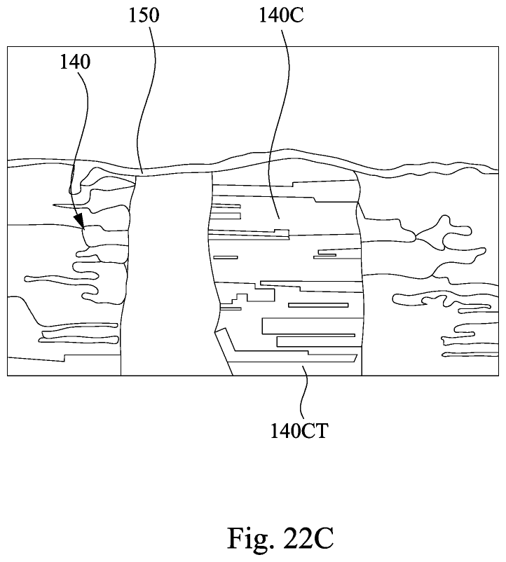

FIG. 22A is an image of a cross-sectional view of a nanotwinned copper conductive feature 140 and a Sn layer 150 thereon according to some embodiments of the present disclosure. FIG. 22B is an image of a cross-sectional view of a nanotwinned copper conductive feature 140 and a Pd layer 150 thereon according to some embodiments of the present disclosure. FIG. 22C is an image of a cross-sectional view of a nanotwinned copper conductive feature 140 and an Ag layer 150 thereon according to some embodiments of the present disclosure. From FIGS. 22A-22C, it can be observed that the silver/palladium/tin cap layer 150 is a continuous thin film with uniform thickness, and that no void is obviously observed at an interface between the cap layer 150 and the nanotwinned copper conductive feature 140.

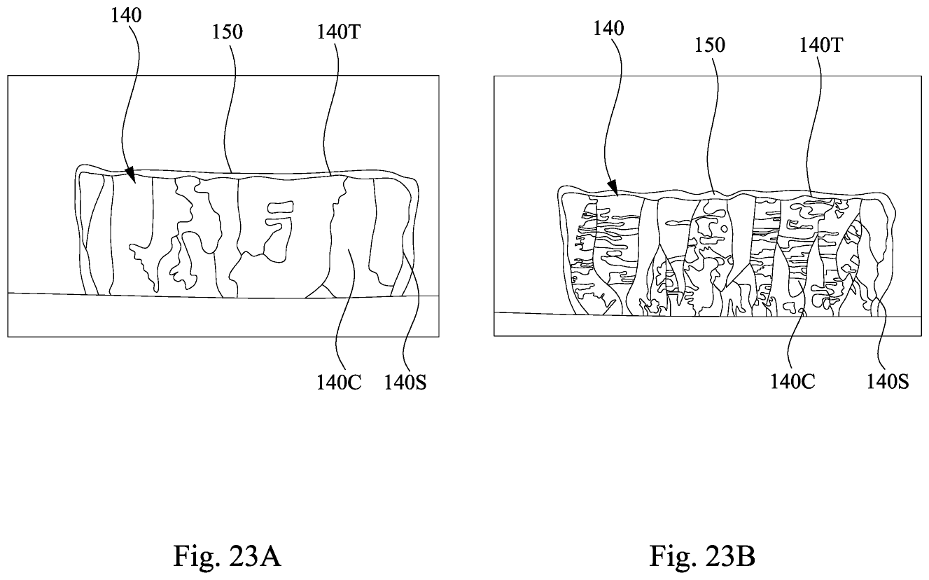

FIG. 23A is an electron beam image of a cross-sectional view of a nanotwinned copper conductive feature 140 and a Sn layer 150 thereon according to some embodiments of the present disclosure. FIG. 23B is an ion beam image of a cross-sectional view of a nanotwinned copper conductive feature 140 and a Sn layer 150 thereon according to some embodiments of the present disclosure. The top surface 140T and opposite sidewalls 140S of a highly-textured <111> twinned copper feature 140 is coated with a Sn cap layer 150 by a selective deposition process (e.g., immersion plating process), thereby protecting the copper feature 140 from oxidation and enhance the electromigration lifetime of the copper feature 140. The boundaries 150CT contained in column/cone structures 140C included in one nanotwinned copper conductive feature 140 can be observed in the ion beam image.

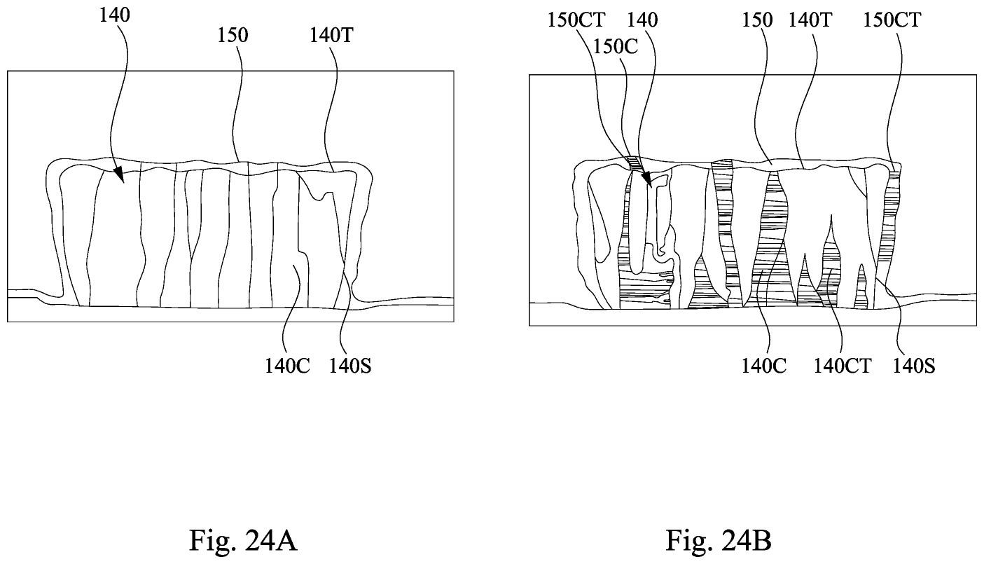

FIG. 24A is an electron beam image of a cross-sectional view of a nanotwinned copper conductive feature and an Ag layer thereon according to some embodiments of the present disclosure. FIG. 24B is an ion beam image of a cross-sectional view of a nanotwinned copper conductive feature and an Ag layer thereon according to some embodiments of the present disclosure. The top surface 140T and opposite sidewalls 140S of a highly-textured <111> twinned copper feature 140 is coated with the Ag cap layer 150 by a selective deposition process (e.g., immersion plating process), thereby protecting the copper feature 140 from oxidation and enhance the electromigration lifetime of the copper feature 140.

In some embodiments, the recipe/compositions of the solution (referred to as first plating solution in the context) used in the selective deposition process is selected such that the growth of the Ag cap layer 150 may follow the crystal growth orientation of the copper feature 140. As a result, a portion or an entirety of the Ag cap layer 150 may have highly-textured <111> twinned metal. The Ag cap layer 150 may be referred to as a nanotwinned silver layer 150. There are many column/cone structures 150C included in one nanotwinned silver layer 150. Each of the column/cone structures 150C may include a nano-twinned crystal containing a plurality of coherent and incoherent twin boundaries 150CT. The boundaries 150CT contained in column/cone structures 150C included in one nanotwinned silver layer 150 can be observed in the ion beam image.

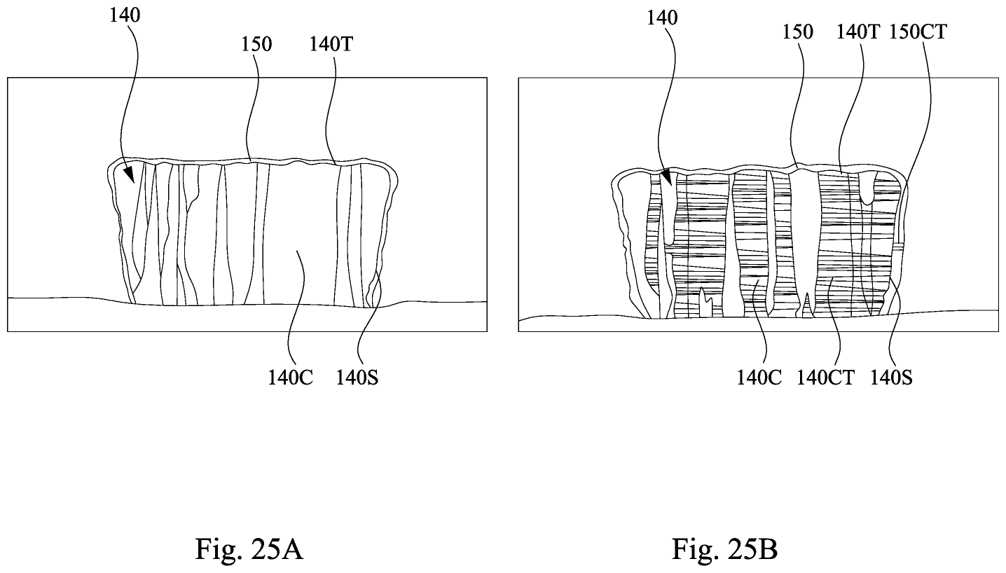

FIG. 25A is an electron beam image of a cross-sectional view of a nanotwinned copper conductive feature and a thin Ag layer thereon according to some embodiments of the present disclosure. FIG. 25B is an ion beam image of a cross-sectional view of a nanotwinned copper conductive feature and a thin Ag layer thereon according to some embodiments of the present disclosure. The top surface 140T and opposite sidewalls 140S of a highly-textured <111> twinned copper feature 140 is coated with the thin Ag cap layer 150 by a selective deposition process (e.g., immersion plating process), thereby protecting the copper feature 140 from oxidation and enhance the electromigration lifetime of the copper feature 140.

In some embodiments, the recipe/compositions of the solution (referred to as first plating solution in the context) used in the selective deposition process is selected such that the growth of the Ag cap layer 150 may follow the crystal growth orientation of the copper feature 140. As a result, a portion or an entirety of the Ag cap layer 150 may have highly-textured <111> twinned metal. There are many column/cone structures included in one nanotwinned silver layer 150. Each of the column/cone structures may include a nano-twinned crystal containing a plurality of coherent and incoherent twin boundaries 150CT.

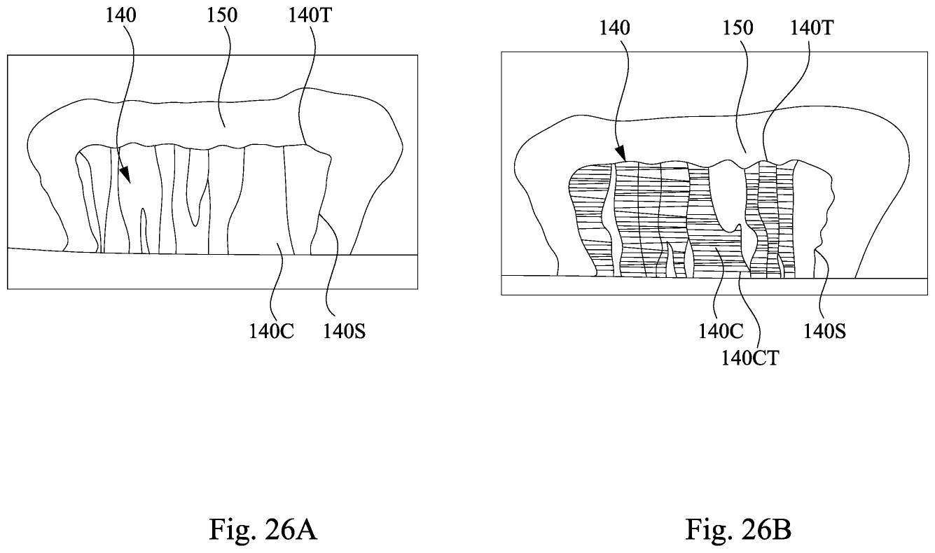

FIG. 26A is an electron beam image of a cross-sectional view of a nanotwinned copper conductive feature and a thick Ag layer thereon according to some embodiments of the present disclosure. FIG. 26B is an ion beam image of a cross-sectional view of a nanotwinned copper conductive feature and a thick Ag layer thereon according to some embodiments of the present disclosure. The top surface 140T and opposite sidewalls 140S of a highly-textured <111> twinned copper feature 140 is coated with the thick Ag cap layer 150 by a selective deposition process (e.g., immersion plating process), thereby protecting the copper feature 140 from oxidation and enhance the electromigration lifetime of the copper feature 140. In the present embodiments, the growth of the Ag cap layer 150 is controlled not to follow the crystal growth orientation of the copper feature 140. For example, in the present embodiments, the selective deposition process (e.g., immersion plating process) may use a electroless-plating or immersion-plating solution having the recipe/compositions different from the recipe/compositions of the first plating solution used in the selective deposition process (e.g., immersion plating process) in the embodiments of FIGS. 24A and 24B, such that the Ag cap layer 150 in the present embodiments may be free of the highly-textured <111> twinned metal. This electroless-plating or immersion-plating solution that does not form the highly-textured <111> twinned metal may be referred to as a second plating solution in the context.

In these embodiments, the Ag cap layer 150 in FIGS. 24A and 24B is designed with a first thickness greater than a second thickness of the thin Ag cap layer 150 in FIGS. 25A and 25B and less than a third thickness of the thick Ag cap layer 150 in FIGS. 25A and 25B. For example, the first thickness may be in a range from about 400 nanometers to about 600 nanometers, the second thickness may be in a range from about 100 nanometers to about 300 nanometers, and the third thickness may be in a range from about 1 micrometer to about 3 micrometers. The thickness of the cap layer 150 can be controlled by the plating time of the selective plating process (e.g., duration that the structure is immersed to be plated into the bath).

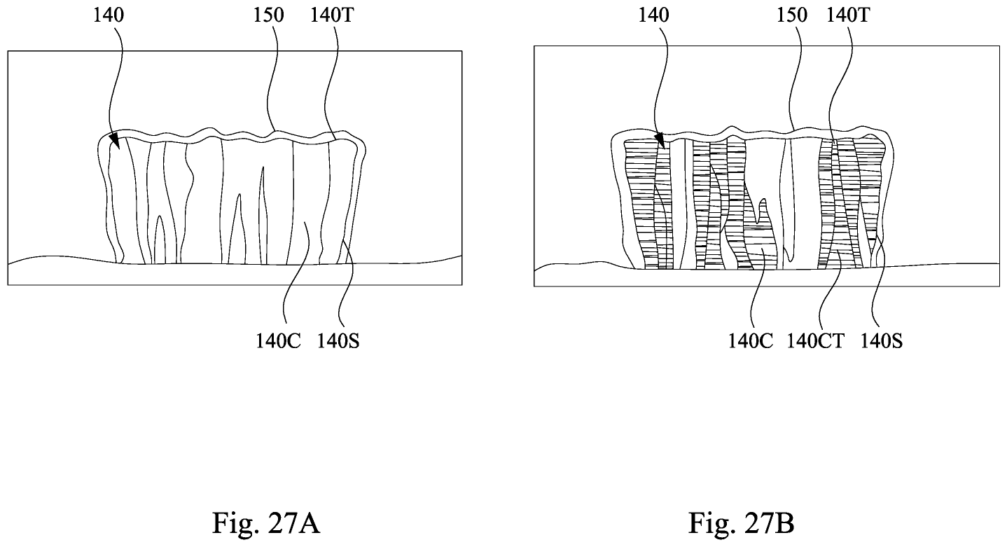

FIG. 27A is an electron beam image of a cross-sectional view of a nanotwinned copper conductive feature 140 and an Ag layer 150 thereon according to some embodiments of the present disclosure. FIG. 27B is an ion beam image of a cross-sectional view of a nanotwinned copper conductive feature 140 and an Ag layer 150 thereon according to some embodiments of the present disclosure. Details of the present embodiments are similar to that of the embodiments of FIGS. 24A and 24B, except that the growth of the Ag cap layer 150 is controlled not to follow the crystal growth orientation of the copper feature 140. For example, in the present embodiments, the selective deposition process (e.g., immersion plating process) may use a second plating solution having the recipe/compositions different from the recipe/compositions of the first plating solution used in the selective deposition process (e.g., immersion plating process) in the embodiments of FIGS. 24A and 24B, such that the Ag cap layer 150 in the present embodiments may be free of the highly-textured <111> twinned metal. In the present embodiments, the Ag cap layer 150 may be designed with a thickness in a range from about 200 nanometers to about 400 nanometers. The top surface 140T and opposite sidewalls 140S of a highly-textured <111> twinned copper feature 140 is coated with the Ag cap layer 150 by a selective deposition process (e.g., immersion plating process), thereby protecting the copper feature 140 from oxidation and enhance the electromigration lifetime of the copper feature 140.

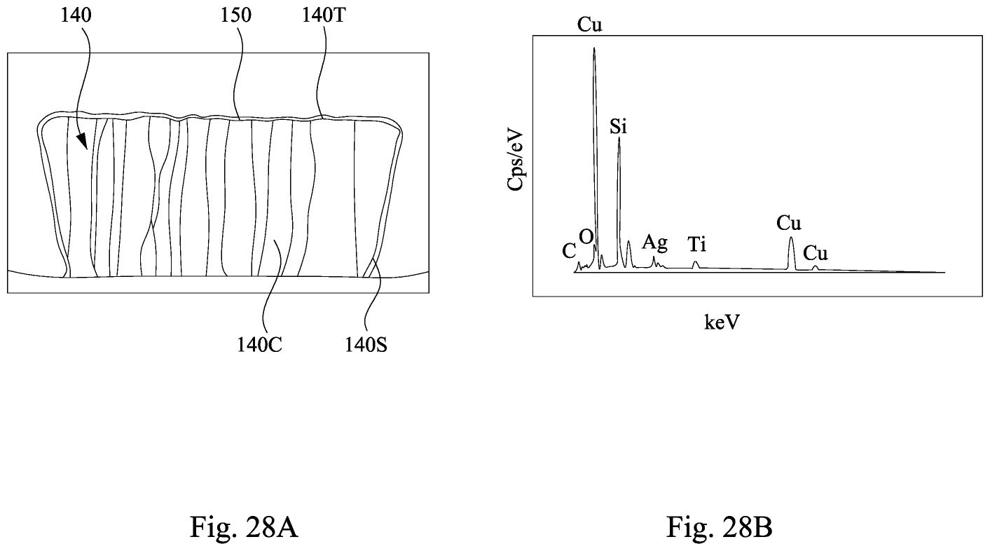

FIG. 28A is an electron beam image of a cross-sectional view of a nanotwinned copper conductive feature 140 and a thin Ag layer 150 thereon after an annealing process according to some embodiments of the present disclosure. In the present embodiments, the Ag cap layer 150 may be designed with a thickness in a range from about 100 nanometers to about 300 nanometers by using the first plating solution in the selective plating process. After depositing the thin Ag layer 150 over the nanotwinned copper conductive feature 140, an annealing process is performed at a temperature ranging from 150 degrees Celsius to about 250 degrees Celsius for a time duration in a range from 1 minute to about 60 minutes. If the temperature is greater than about 250 degrees Celsius and/or the time duration is greater than about 60 minutes, an ability of the Ag layer 150 protect the copper feature 140 from oxidation may degrade. If the temperature is less than about 150 degrees Celsius and/or the time duration is less than about 1 minute, stress force remains in the Ag layer 150, and lead to crack in the Ag layer 150. FIG. 28B is energy-dispersive X-ray spectroscopy (EDS) result of the package structure shown in FIG. 28A. In FIG. 28B, little or no oxide element is observed in the package structure, which indicates that there is no obvious oxide layer over the copper conductive feature 140. The thin Ag layer 150 can well protect the copper conductive feature 140 from oxidation.

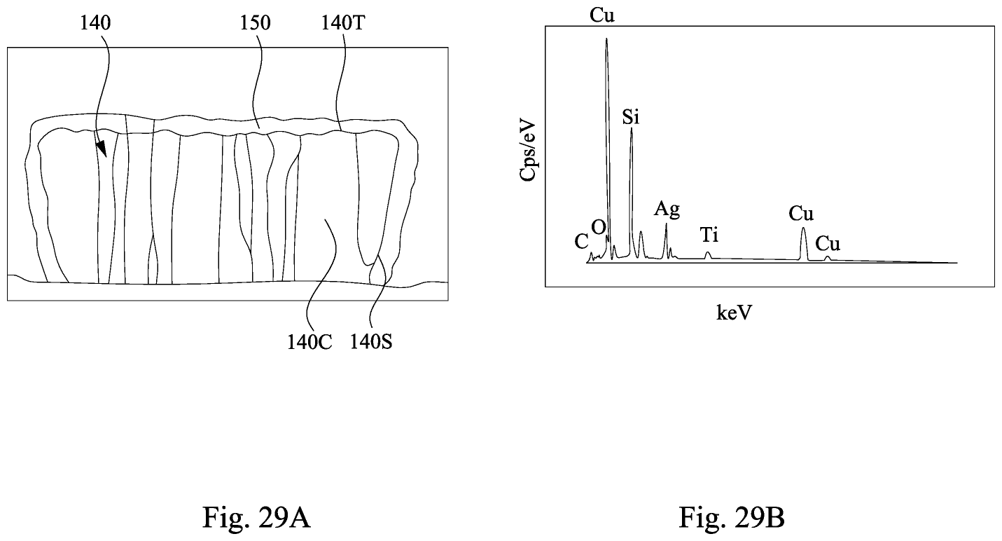

FIG. 29A is an electron beam image of a cross-sectional view of a nanotwinned copper conductive feature 140 and a thick Ag layer 150 thereon after an annealing process according to some embodiments of the present disclosure. In the present embodiments, the Ag cap layer 150 may be designed with a thickness in a range from about 400 nanometers to about 600 nanometers by using the first plating solution in the selective plating process. After depositing the thick Ag layer 150 over the nanotwinned copper conductive feature 140, an annealing process is performed at a temperature ranging from 150 degrees Celsius to about 250 degrees Celsius for a time duration in a range from 1 minutes to about 60 minutes. If the temperature is greater than about 250 degrees Celsius and/or the time duration is greater than about 60 minutes, an ability of the Ag layer 150 protect the copper feature 140 from oxidation may degrade. If the temperature is less than about 150 degrees Celsius and/or the time duration is less than about 1 minute, stress force remains in the Ag layer 150, and lead to crack in the Ag layer 150. FIG. 29B is energy-dispersive X-ray spectroscopy (EDS) result of a package structure shown in FIG. 29A. In FIG. 29B, little or no oxide element is observed in the package structure, which indicates that there is no obvious oxide layer over the copper conductive feature 140. The thick Ag layer 150 can well protect the copper conductive feature 140 from oxidation.

Based on the above discussions, it can be seen that the present disclosure offers advantages to the package device. It is understood, however, that other embodiments may offer additional advantages, and not all advantages are necessarily disclosed herein, and that no particular advantage is required for all embodiments. One advantage is that top surface and opposite sidewalls of a highly-textured <111> twinned copper wire is coated with a metal cap layer by a selective deposition process (e.g., electroless plating process or immersion plating process), thereby protecting the copper wire from oxidation and enhance the electromigration lifetime of the copper wire, which is beneficial for redistribution layer in 2.5D package and 3D package technology. Another advantage is that the silver cap layer, the palladium cap layer, and the tin cap layer are continuous thin films with uniform thickness, and that no void is obviously observed at an interface between the cap layer and the copper. Still another advantage is that compared to a sputtering process, the selective deposition process (e.g., electroless plating process or immersion plating process) can deposit materials at positions of the copper wires, which is more convenience and easier and cost less. Still another advantage is that a portion of the metal cap layer (e.g., the silver cap layer) has the nano-twin crystal structure when the immersion plating process is performed. Still another advantage is that a thickness of the deposited metal cap layer can be adjust by immersion time when the immersion plating process is performed, and the deposition rate thereof is greater than that of physical vapor deposition (PVD) and chemical vapor deposition (CVD). Still another advantage is that a melting point of oxides of the metal cap layer is high enough for allowing the package structure to operate at a wide temperature range.

According to some embodiments of the present disclosure, a method includes forming a redistribution structure, wherein the redistribution structure comprises a first conductive feature and a dielectric layer around the first conductive feature, the first conductive feature comprising nano-twinned copper; depositing a metal cap layer over the first conductive feature, wherein the metal cap layer has a first portion extending along a top surface of the first conductive feature and a second portion extending along a sidewall of the first conductive feature; and bonding the first portion of the metal cap layer over the first conductive feature of the redistribution structure with a second conductive feature of a device.

According to some embodiments of the present disclosure, a method includes forming a first conductive feature over an interconnect structure over a substrate, wherein the first conductive feature comprises nano-twinned copper; forming a passivation layer over the first conductive feature, wherein the passivation layer covers a first portion of the first conductive feature, and exposes a second portion of the first conductive feature; and selectively depositing a metal cap layer over the exposed second portion of the first conductive feature, wherein at least a portion of a top surface of the passivation layer is free of a metal material of the metal cap layer.

According to some embodiments of the present disclosure, a package structure includes a redistribution structure, wherein the redistribution structure comprises a first conductive feature and a dielectric layer around the first conductive feature, the first conductive feature comprising nano-twinned copper; a metal cap layer over the first conductive feature, wherein the metal cap layer has a first portion extending along a top surface of the first conductive feature and a second portion extending along a sidewall of the first conductive feature; and a device comprising a second conductive feature bonded with the first portion of the metal cap layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a redistribution structure, wherein the redistribution structure comprises a first conductive feature and a dielectric layer around the first conductive feature, the first conductive feature comprising nano-twinned copper;
depositing a metal cap layer over the first conductive feature, wherein the metal cap layer has a first portion extending along a top surface of the first conductive feature and a second portion extending along a sidewall of the first conductive feature; and
bonding the first portion of the metal cap layer over the first conductive feature of the redistribution structure with a second conductive feature of a device.

2. The method of claim 1, wherein selectively depositing the metal cap layer over the first conductive feature is performed without external current.

3. The method of claim 1, wherein selectively depositing the metal cap layer comprises an electroless plating process or an immersion plating process.

4. The method of claim 1, wherein the metal cap layer comprises silver, gold, tin, or palladium.

5. The method of claim 1, wherein the dielectric layer has a portion uncovered by the first conductive feature, and depositing the metal cap layer over the first conductive feature is performed such that the portion of the dielectric layer uncovered by the first conductive feature is free of a metal material of the metal cap layer.

6. The method of claim 1, wherein bonding the first portion of the metal cap layer over the first conductive feature of the redistribution structure with the second conductive feature of the device comprises:
forming a connector over the first portion of the metal cap layer; and
attaching the connector to the second conductive feature of the device.

7. The method of claim 1, wherein depositing the metal cap layer is performed such that a part of the first portion of the metal cap layer comprises nano-twinned metal.

8. The method of claim 1, wherein depositing the metal cap layer is performed such that a part of the second portion of the metal cap layer comprises nano-twinned metal.

9. The method of claim 1, further comprising:
forming an interconnect structure over a substrate, wherein the redistribution structure is formed over the interconnect structure.

10. A method, comprising:
forming a first conductive feature over an interconnect structure over a substrate, wherein the first conductive feature comprises nano-twinned copper;
forming a passivation layer over the first conductive feature, wherein the passivation layer covers a first portion of the first conductive feature, and exposes a second portion of the first conductive feature; and
selectively depositing a metal cap layer over the exposed second portion of the first conductive feature, wherein at least a portion of a top surface of the passivation layer is free of a metal material of the metal cap layer.

11. The method of claim 10, wherein selectively depositing the metal cap layer comprises an electroless plating process or an immersion plating process.

12. The method of claim 11, wherein forming the first conductive feature comprises an electroplating process.

13. The method of claim 10, wherein the metal cap layer comprises silver, gold, tin, or palladium.

14. The method of claim 10, wherein selectively depositing the metal cap layer is performed such that the metal cap layer comprises nano-twinned metal.

15. The method of claim 10, further comprises:
bonding the metal cap layer over the first conductive feature with a second conductive feature of a device.

16. The method of claim 15, wherein bonding the metal cap layer over the first conductive feature the second conductive feature of the device comprises:
forming a connector over the metal cap layer; and
attaching the connector to the second conductive feature of the device.

17. A package structure, comprising:
a redistribution structure, wherein the redistribution structure comprises a first conductive feature, the first conductive feature comprising nano-twinned copper;
a metal cap layer over the first conductive feature, wherein the metal cap layer has a first portion extending along a top surface of the first conductive feature and a second portion extending along a sidewall of the first conductive feature; and
a device comprising a second conductive feature bonded with the first portion of the metal cap layer.

18. The package structure of claim 17, further comprising:
a connector bonding the second conductive feature to the first portion of the metal cap layer.

19. The package structure of claim 17, wherein the metal cap layer comprises nano-twinned metal.

20. The package structure of claim 17, wherein the metal cap layer comprises silver, gold, tin, or palladium.
